(19) United States
(12) Patent Application Publication
(10) Pub. No.: US 2024/0321699 A1
(43) Pub. Date: Sep. 26, 2024

(54) SEMICONDUCTOR MODULE AND SEMICONDUCTOR DEVICE

(71) Applicant: ROHM CO., LTD., Kyoto-shi (JP)

(72) Inventors: Yo MOCHIZUKI, Kyoto-shi (JP); Kazunori FUJI, Kyoto-shi (JP)

(21) Appl. No.: 18/733,196

(22) Filed: Jun. 4, 2024

Related U.S. Application Data
(63) Continuation of application No. PCT/JP2022/043948, filed on Nov. 29, 2022.

(30) Foreign Application Priority Data
Dec. 16, 2021 (JP) 2021-204569

(51) Int. Cl. H01L 23/495; H01L 23/10

(52) U.S. Cl. CPC H01L 23/49568; H01L 23/10; H01L 23/4952

(57) ABSTRACT

A semiconductor module includes a conductive member, a semiconductor element, and a heat transfer layer. The conductive member includes a first obverse surface facing in a thickness direction. The semiconductor element includes a first electrode and a first gate electrode that face the first obverse surface and a second electrode opposite to the side facing the first obverse surface. The first electrode connects to the conductive member. The heat transfer layer between the first obverse surface and the semiconductor element is conductively bonded to the first obverse surface, and connected to the first electrode. The heat transfer layer includes a first surface facing the first obverse surface and a second surface facing the semiconductor element. The second surface is spaced from the first gate electrode as viewed in the thickness direction. The second surface is surrounded by the periphery of the first surface as viewed in the thickness direction.

### TECHNICAL FIELD

The present disclosure relates to a semiconductor module and a semiconductor device.

### BACKGROUND ART

Semiconductor modules with semiconductor elements having a switching function mounted therein are conventionally known. Such a semiconductor module is mainly used for power conversion. JP-A-2013-258387 discloses an example of such a semiconductor module.

The semiconductor element mounted in the semiconductor module disclosed in JP-A-2013-258387 has a source electrode and a drain electrode located on opposite sides of each other. A top plate electrode is conductively bonded to the source electrode. A drain electrode pattern is conductively bonded to the drain electrode. The semiconductor element is located between the top plate electrode and the drain electrode pattern. Such a configuration can reduce the parasitic resistance in the semiconductor module while achieving downsizing of the semiconductor module. However, the area of the source electrode is generally smaller than the area of the drain electrode. In the semiconductor module, therefore, the amount of heat dissipation from the source electrode to the top plate electrode is small compared with the amount of heat dissipation from the drain electrode to the drain electrode pattern, resulting in insufficient heat dissipation from the semiconductor device.

### BRIEF DESCRIPTION OF THE DRAWINGS

FIG. 1 is a plan view of a semiconductor module according to a first embodiment of the present disclosure.

FIG. 2 is a plan view corresponding to FIG. 1, in which the sealing resin is transparent.

FIG. 3 is a plan view corresponding to FIG. 2, in which the third conductive member is also transparent.

FIG. 4 is a bottom view of the semiconductor module shown in FIG. 1.

FIG. 5 is a sectional view taken along line V-V in FIG. 2.

FIG. 6 is a sectional view taken along line VI-VI in FIG. 2.

FIG. 7 is a sectional view taken along line VII-VII in FIG. 2.

FIG. 8 is a sectional view taken along line VIII-VIII in FIG. 2.

FIG. 9 is a partial enlarged view of FIG. 3, showing a second semiconductor element and the nearby portion.

FIG. 10 is a sectional view taken along line X-X in FIG. 9.

FIG. 11 is a partial enlarged view of FIG. 3, which shows a first semiconductor element and the nearby portion and in which the first semiconductor element is transparent.

FIG. 12 is a sectional view taken along line XII-XII in FIG. 11.

FIG. 13 is a sectional view taken along line XIII-XIII in FIG. 11.

FIG. 14 is a partial enlarged view of FIG. 12.

FIG. 15 is a partially enlarged plan view of semiconductor module according to a variation of the first embodiment of the present disclosure, in which the sealing resin is omitted while the third conductive member and the first semiconductor element are transparent.

FIG. 16 is a sectional view taken along line XVI-XVI in FIG. 15.

FIG. 17 is a partially enlarged sectional view of a semiconductor module according to a second embodiment of the present disclosure.

FIG. 18 is a partially enlarged sectional view of the semiconductor module shown in FIG. 17, of which sectional position is different from that of FIG. 17.

FIG. 19 is a partial enlarged view of FIG. 17.

FIG. 20 is a partially enlarged sectional view of a semiconductor module according to a third embodiment of the present disclosure.

FIG. 21 is a partially enlarged sectional view of the semiconductor module shown in FIG. 20, of which sectional position is different from that of FIG. 20.

FIG. 22 is a plan view of a semiconductor module according to a fourth embodiment of the present disclosure, in which the sealing resin is transparent.

FIG. 23 is a plan view of a semiconductor device according to an embodiment of the present disclosure, in which the sealing resin and the first semiconductor element are transparent.

FIG. 24 is a bottom view of the semiconductor device shown in FIG. 23.

FIG. 25 is a sectional view taken along line XXV-XXV in FIG. 23.

FIG. 26 is a sectional view taken along line XXVI-XXVI in FIG. 23.

FIG. 27 is a sectional view taken along line XXVII-XXVII in FIG. 23.

FIG. 28 is a partial enlarged view of FIG. 25.

### DETAILED DESCRIPTION OF EMBODIMENTS

The following describes modes for carrying out the present disclosure with reference to the drawings.

### First Embodiment

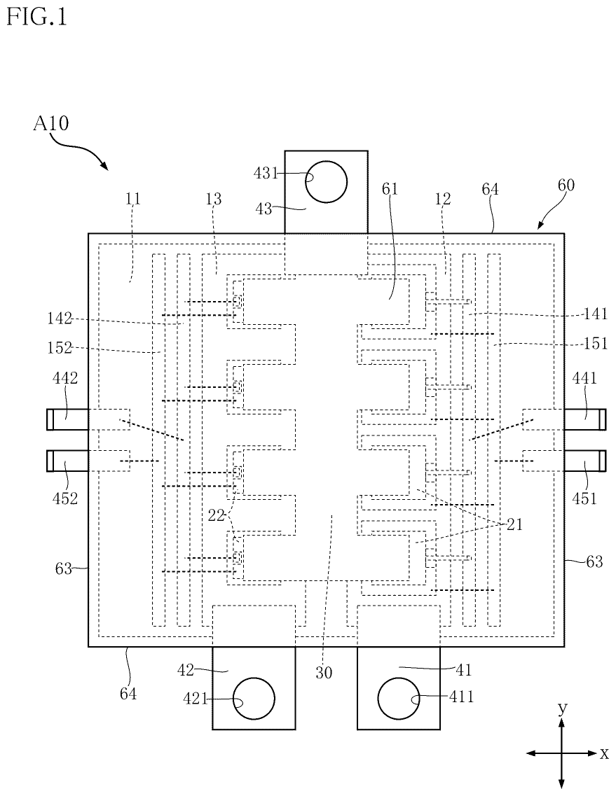

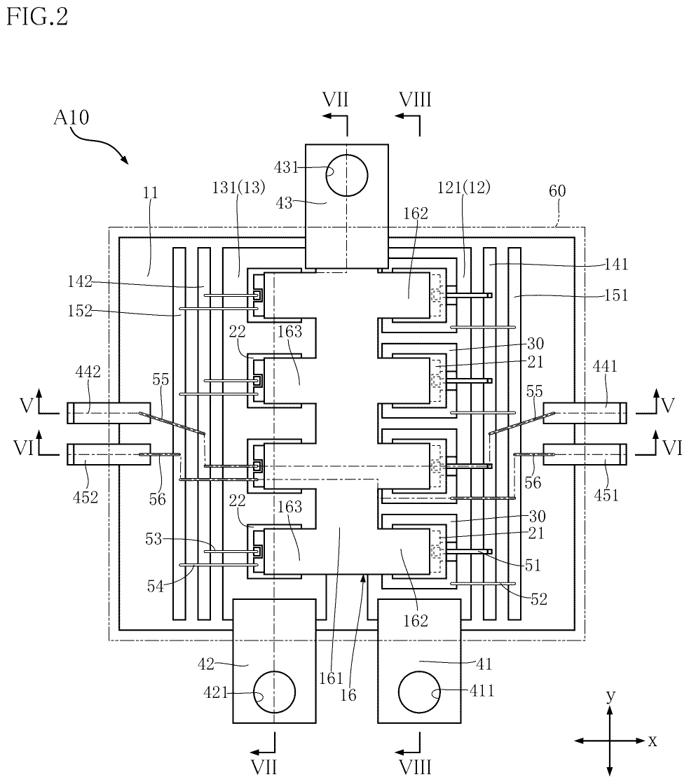

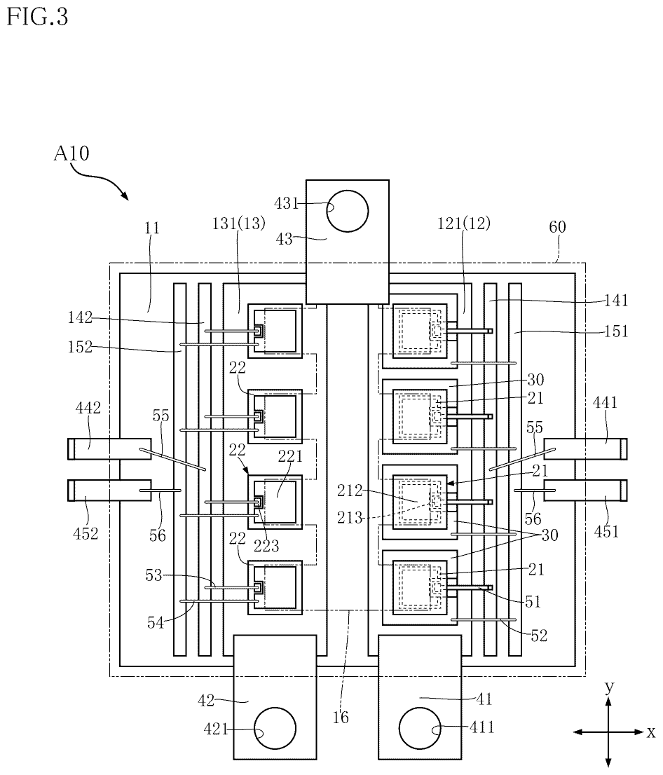

A semiconductor module A10 according to a first embodiment of the present disclosure will be described based on FIGS. 1 to 14. The semiconductor module A10 includes a substrate 11, a first conductive member 12, a second conductive member 13, a plurality of first semiconductor elements 21, a plurality of second semiconductor elements 22, a plurality of heat transfer layers 30, a third conductive member 16, a first input terminal 41, a second input terminal 42, an output terminal 43, and a sealing resin 60. The semiconductor module A10 further includes a first gate wiring layer 141, a second gate wiring layer 142, a first detection wiring layer 151, a second detection wiring layer 152, a heat dissipation layer 17, a first gate terminal 441, a second gate terminal 442, a first detection terminal 451, and a second detection terminal 452. For the convenience of understanding, the sealing resin 60 is transparent in FIG. 2. As compared with FIG. 2, the third conductive member 16 is additionally transparent in FIG. 3 for the convenience of understanding. As compared with FIG. 3, the first semiconductor element 21 is additionally transparent in FIG. 11 for the convenience of understanding. The outline of the sealing resin 60 is shown by imaginary lines (dash-double dot lines) in FIGS. 2 and 3. The outline of the third conductive member 16 is shown by imaginary lines in FIGS. 3 and 11. The first semiconductor element 21 is shown by imaginary lines in FIG. 11. In FIG. 2, the V-V line, the VI-VI line, and the VII-VII line are shown as dash-single dot lines.

In the description of the semiconductor module A10, the direction which is normal to the first obverse surface 121 (described later) of the first conductive member 12 referred to as the “thickness direction z” for convenience. A direction orthogonal to the thickness direction z is referred to as the “first direction x” . The direction orthogonal to the thickness direction Z and the first direction x is referred to as the “second direction y”.

The semiconductor module A10 converts the DC power supply voltage applied to the first input terminal 41 and the second input terminal 42 into AC power by the first semiconductor elements 21 and the second semiconductor elements 22. The converted AC power is inputted through the output terminal 43 to a power supply target, such as a motor. The semiconductor module A10 forms a part of a power conversion circuit, such as an inverter.

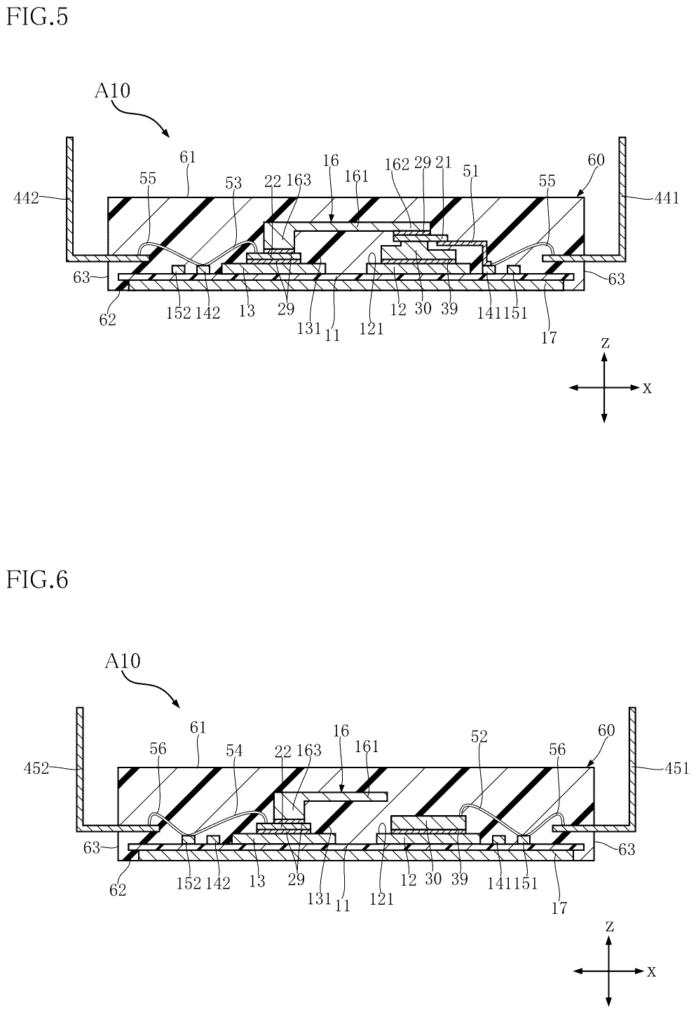

As shown in FIGS. 5 and 7, the substrate 11 supports the first conductive member 12, the second conductive member 13, the first gate wiring layer 141, the second gate wiring layer 142, the first detection wiring layer 151, the second detection wiring layer 152, and the heat dissipation layer 17. The substrate 11 is electrically insulating. The substrate 11 is made of a material with relatively high thermal conductivity. The substrate 11 may be made of ceramics containing aluminum nitride (AlN), for example. The periphery of the substrate 11 is enclosed in the sealing resin 60 in the thickness direction z. The thickness of the substrate 11 is smaller than the thickness of each of the first conductive member 12, the second conductive member 13, and the heat dissipation layer 17.

The first conductive member 12 is supported on the substrate 11 as shown in FIGS. 2, 3, and 8. The first semiconductor elements 21 and the heat transfer layers 30 are mounted on the first conductive member 12. The first conductive member 12 is rectangular in shape with the long side along the second direction y. As viewed in the thickness direction z, the first conductive member 12 is surrounded by the periphery of the substrate 11. The composition of the first conductive member 12 includes copper (Cu). The first conductive member 12 has a first obverse surface 121 facing in the thickness direction z. The first semiconductor elements 21 and the heat transfer layers 30 face the first obverse surface 121.

The second conductive member 13 is supported on the substrate 11 as shown in FIGS. 2, 3, and 7. The second semiconductor elements 22 are mounted on the second conductive member 13. The second conductive member 13 is spaced apart from the first conductive member 12 in the first direction x. The second conductive member 13 is rectangular in shape with the long side along the second direction y. The second conductive member 13 is surrounded by the periphery of the substrate 11 as viewed in the thickness direction z. The composition of the second conductive member 13 includes copper. The second conductive member 13 has a second obverse surface 131 facing the same side as the first obverse surface 121 of the first conductive member 12 in the thickness direction z. The second semiconductor elements 22 face the second obverse surface 131.

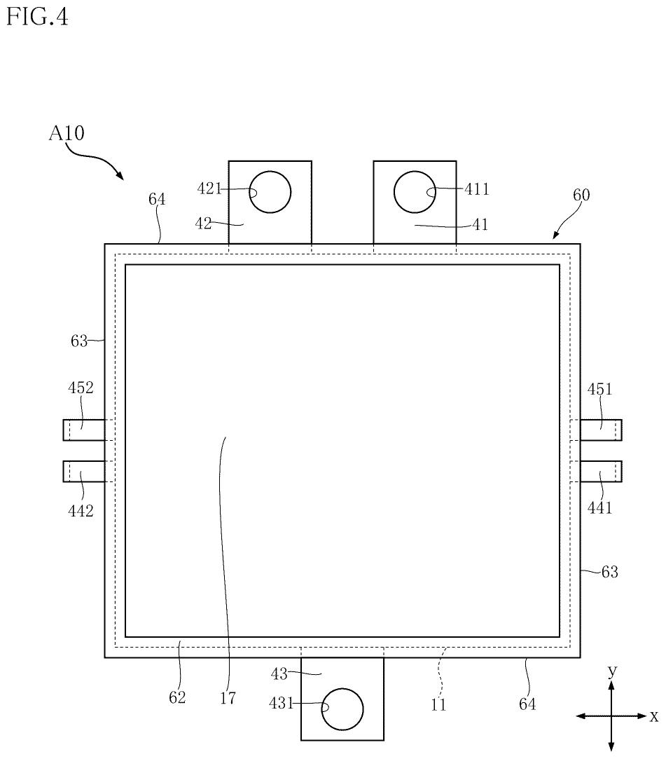

As shown in FIGS. 5 to 8, the heat dissipation layer 17 is located opposite to the first conductive member 12 and the second conductive member 13 with respect to the substrate 11 in the thickness direction z. The heat dissipation layer 17 is supported on the substrate 11. The heat dissipation layer 17 is exposed from the sealing resin 60. The volume of the heat dissipation layer 17 is greater than the sum of the volumes of the first conductive member 12 and the second conductive member 13. As shown in FIG. 4, the heat dissipation layer 17 is surrounded by the periphery of the substrate 11 as viewed in the thickness direction z. The composition of the heat dissipation layer 17 includes copper. When the semiconductor module A10 is used, a heat sink (not shown) is bonded to the heat dissipation layer 17.

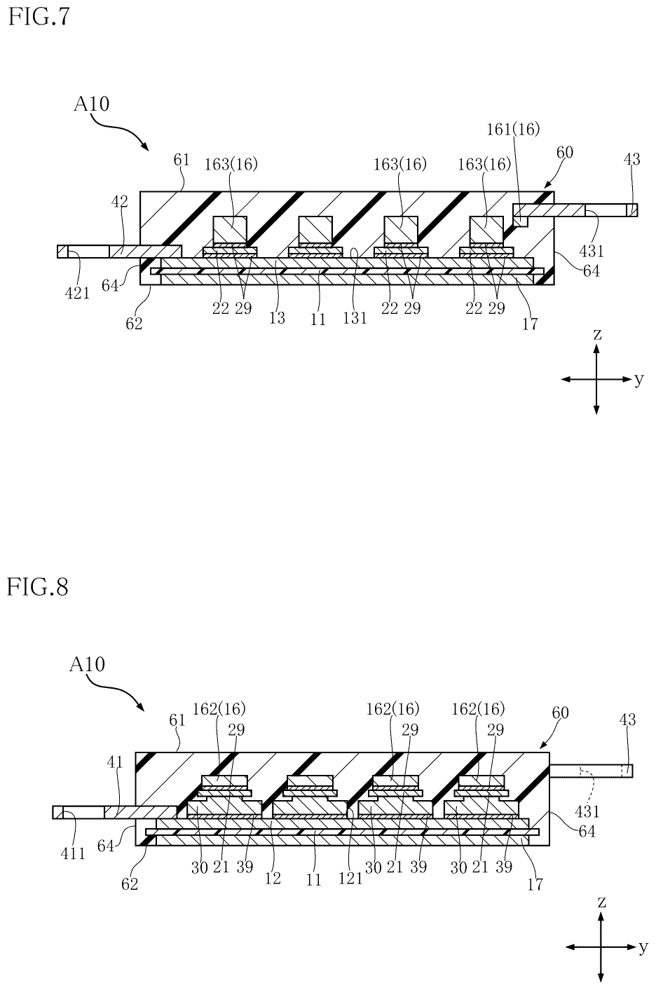

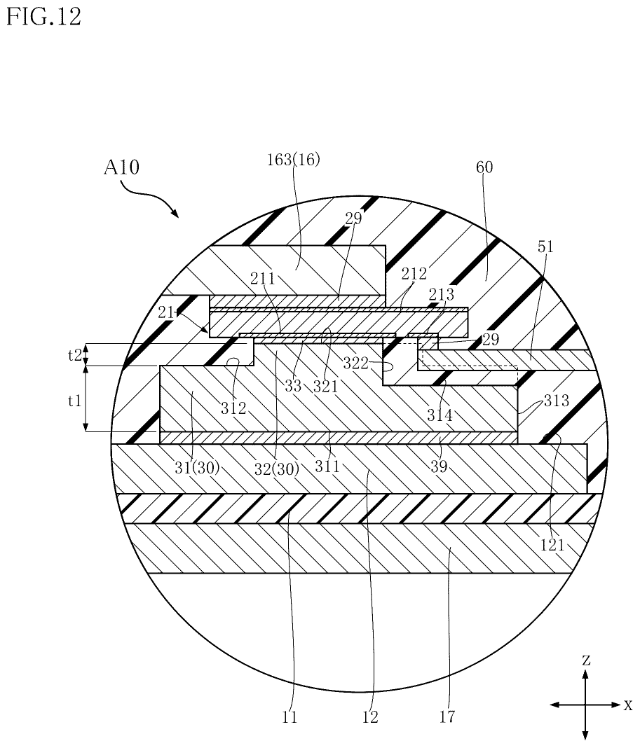

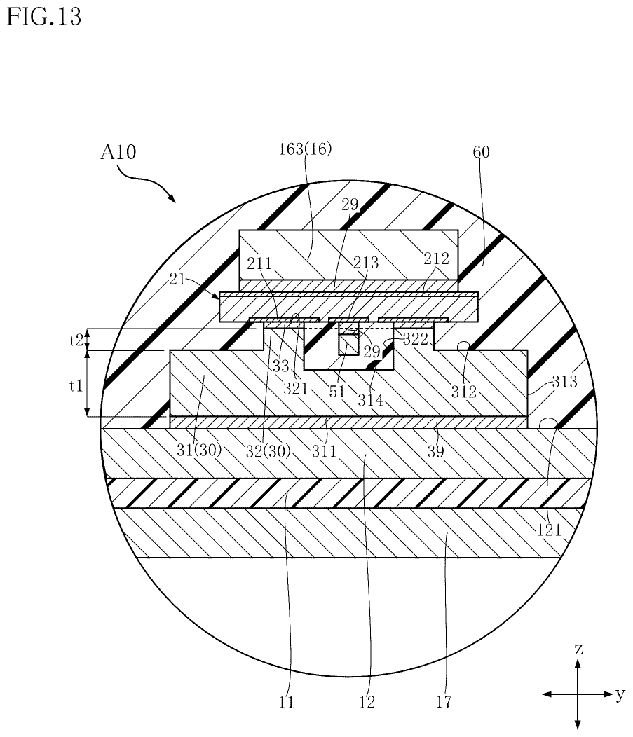

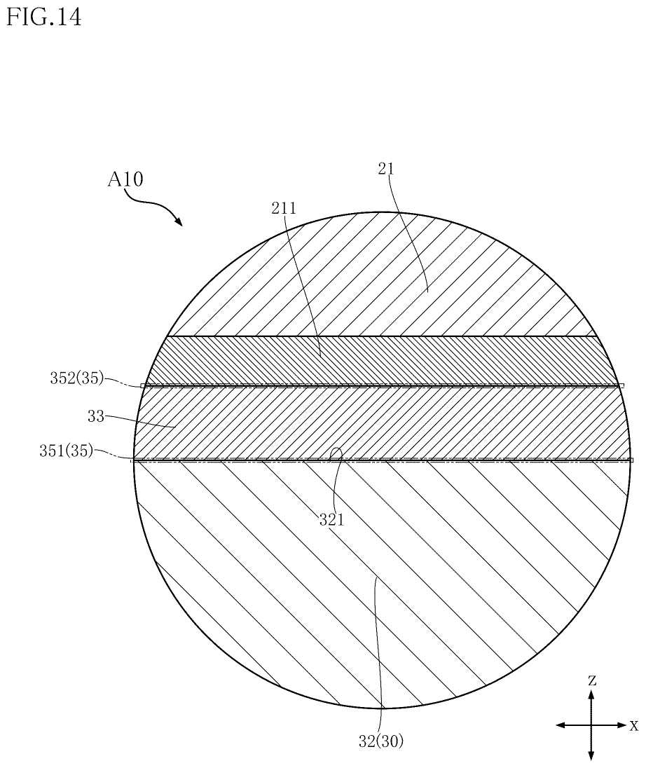

As shown in FIGS. 5 and 8, the first semiconductor elements 21 are bonded to the heat transfer layers 30. The first semiconductor elements 21 are identical with each other. The first semiconductor elements 21 are MOSFETs (Metal-Oxide-Semiconductor Field-Effect Transistor), for example. Alternatively, the first semiconductor elements 21 may be field effect transistors including MISFETs (Metal-Insulator-Semiconductor Field-Effect Transistor) or bipolar transistors such as IGBTs (Insulated Gate Bipolar Transistor). In the semiconductor module A10 described herein, the first semiconductor elements 21 are n-channel MOSFETs of a vertical structure type. The first semiconductor elements 21 include a compound semiconductor substrate. The composition of the compound semiconductor substrate includes silicon carbide (SiC). The first semiconductor elements 21 are arranged along the second direction y. As shown in FIGS. 12 and 13, each of the first semiconductor elements 21 has a first electrode 211, a second electrode 212, and a first gate electrode 213.

As shown in FIGS. 12 and 13, the first electrode 211 faces the first obverse surface 121 of the first conductive member 12. A current corresponding to the power after conversion by the first semiconductor element 21 flows in the first electrode 211. That is, the first electrode 211 corresponds to the source electrode of the first semiconductor element 21.

As shown in FIGS. 12 and 13, the second electrode 212 is located on a side opposite to the side facing the first obverse surface 121 of the first conductive member 12 in the thickness direction z. A current corresponding to the power before conversion by the first semiconductor element 21 flows in the second electrode 212. That is, the second electrode 212 corresponds to the drain electrode of the first semiconductor element 21.

As shown in FIGS. 12 and 13, the first gate electrode 213 faces the first obverse surface 121 of the first conductive member 12. Thus, the first gate electrode 213 is located on the same side as the first electrode 211 in the thickness direction z. A gate voltage for driving the first semiconductor element 21 is applied to the first gate electrode 213. As shown in FIG. 11, the area of the first gate electrode 213 is smaller than that of the first electrode 211 as viewed in the thickness direction z.

As shown in FIGS. 5 to 7, the second semiconductor elements 22 are bonded to the second obverse surface 131 of the second conductive member 13. The second semiconductor elements 22 are identical with the first semiconductor elements 21. Thus, the second semiconductor elements 22 are n-channel MOSFETs of a vertical structure type. The second semiconductor elements 22 are arranged along the second direction y.

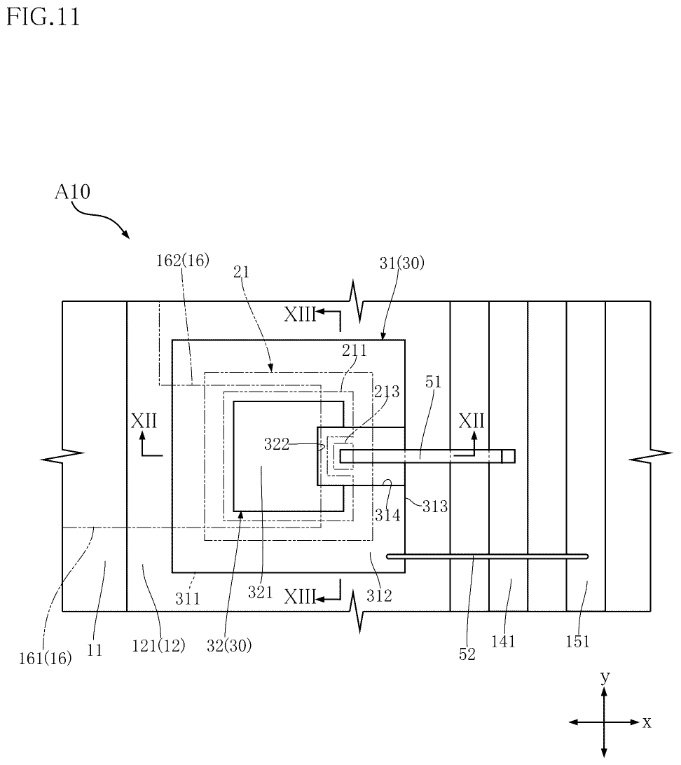

As shown in FIG. 10, each of the second semiconductor elements 22 has a third electrode 221, a fourth electrode 222, and a second gate electrode 223.

As shown in FIG. 10, the third electrode 221 is located on a side opposite to the side facing the second obverse surface 131 of the second conductive member 13 in the thickness direction z. A current corresponding to the power after conversion by the second semiconductor element 22 flows in the third electrode 221. That is, the third electrode 221 corresponds to the source electrode of the second semiconductor element 22.

As shown in FIG. 10, the fourth electrode 222 faces the second obverse surface 131 of the second conductive member 13. A current corresponding to the power before conversion by the second semiconductor element 22 flows in the fourth electrode 222. That is, the fourth electrode 222 corresponds to the drain electrode of the second semiconductor element 22. The fourth electrode 222 is conductively bonded to the second obverse surface 131 via a conductive joining layer 29. In this way, the fourth electrodes 222 of the second semiconductor elements 22 are electrically connected to the second conductive member 13. The conductive joining layer 29 may be solder, for example. Alternatively, the conductive joining layer 29 may be a sintered metal containing silver (Ag), for example.

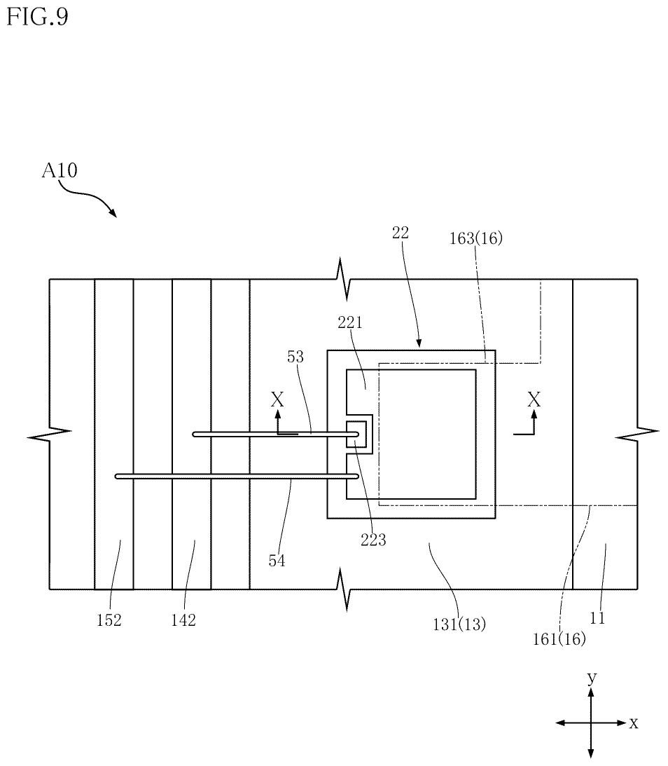

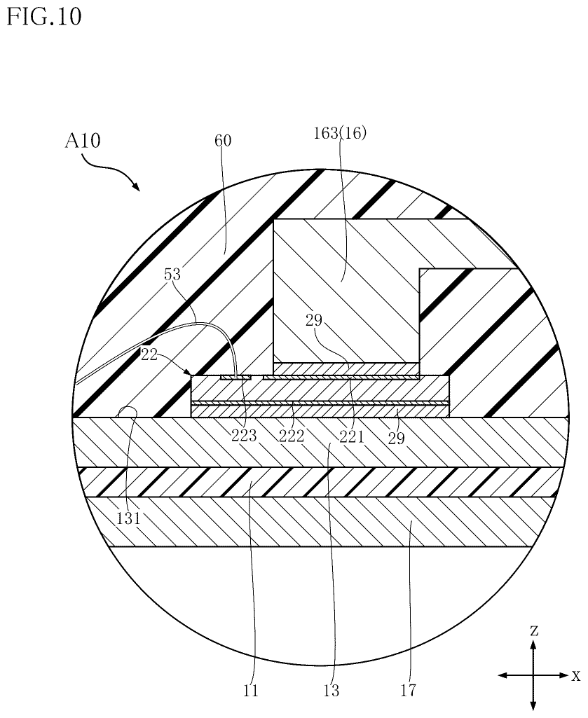

As shown in FIG. 10, the second gate electrode 223 is located on a side opposite to the side facing the second obverse surface 131 of the second conductive member 13 in the thickness direction z. Thus, the second gate electrode 223 is located on the same side as the third electrode 221 in the thickness direction z. A gate voltage for driving the second semiconductor element 22 is applied to the second gate electrode 223. As shown in FIG. 9, the area of the second gate electrode 223 is smaller than that of the third electrode 221 as viewed in the thickness direction z.

In the semiconductor module A10, the first semiconductor elements 21 form a part of an upper arm circuit, and the second semiconductor elements 22 form a part of a lower arm circuit. In the semiconductor module A10, the configuration of the first semiconductor elements 21 is identical to that of the second semiconductor elements 22 inverted about an axis orthogonal to the thickness direction z. Thus, the polarity of the first electrode 211 of each first semiconductor element 21 and the polarity of the fourth electrode 222 of each second semiconductor element 22 differ from each other.

As shown in FIG. 8, the heat transfer layers 30 are bonded to the first obverse surface 121 of the first conductive member 12. The heat transfer layers 30 are arranged along the second direction y. The heat transfer layers 30 are located between the first obverse surface 121 and the first semiconductor elements 21. The number of heat transfer layers 30 is equal to the number of first semiconductor elements 21. The first semiconductor elements 21 are supported on the heat transfer layers 30, respectively. The first electrodes 211 of the first semiconductor elements 21 are electrically connected to the heat transfer layers 30, respectively. As shown in FIGS. 12 and 13, each of the heat transfer layers 30 includes a first layer 31, a second layer 32, a first joining layer 33, and a third joining layer 39. As shown in FIG. 11, the heat transfer layers 30 are rectangular as viewed in the thickness direction z. Alternatively, the heat transfer layers 30 may be circular as viewed in the thickness direction z.

As shown in FIGS. 11 to 13, the first layer 31 has a first surface 311, a third surface 312, and a fourth surface 313. The first surface 311 faces the first obverse surface 121 of the first conductive member 12. The third surface 312 faces away from the first surface 311 in the thickness direction z. The first semiconductor element 21 is surrounded by the periphery of the third surface 312 as viewed in the thickness direction z. The fourth surface 313 faces in the directions orthogonal to the thickness direction z. In the semiconductor module A10, the fourth surface 313 includes a plurality of regions. The composition of the first layer 31 includes copper.

As shown in FIGS. 11 to 13, the first layer 31 is provided with a first recess 314 recessed from the third surface 312 and the fourth surface 313. As viewed in the thickness direction z, the first gate electrode 213 of the first semiconductor element 21 overlaps with the first recess 314.

As shown in FIGS. 12 and 13, the second layer 32 is located between the first layer 31 and the first electrode 211 of the first semiconductor element 21. The second layer 32 is connected to the first layer 31 at the third surface 312. Thus, in the semiconductor module A10, the first layer 31 and the second layer 32 are integral with each other. Accordingly, the composition of the second layer 32 is the same as that of the first layer 31. As shown in FIG. 11, the second layer 32 is surrounded by the periphery of the first semiconductor element 21 as viewed in the thickness direction z. As viewed in the thickness direction z, the second layer 32 is spaced apart from the first gate electrode 213 of the first semiconductor element 21.

The dimension t1 in the thickness direction z of the first layer 31 is greater than the dimension t2 in the thickness direction of the second layer 32. The dimension t1 is 3 to 30 times the dimension t2.

As shown in FIGS. 11 to 13, the second layer 32 has a second surface 321. The second surface 321 faces the first semiconductor element 21. As viewed in the thickness direction z, the second surface 321 is spaced apart from the first gate electrode 213 of the first semiconductor element 21. The second surface 321 is surrounded by the periphery of the first surface 311 of the first layer 31 as viewed in the thickness direction z. In the semiconductor module A10, the area of the second surface 321 is smaller than the area of the first electrode 211 of the first semiconductor element 21.

As shown in FIGS. 11 to 13, the second layer 32 is provided with a second recess 322 recessed in a direction orthogonal to the thickness direction z. The second recess 322 penetrates the second layer 32 in the thickness direction z and is connected to the first recess 314 of the first layer 31. As viewed in the thickness direction z, the second recess 322 overlaps with the first recess 314 and the first gate electrode 213 of the first semiconductor element 21.

As shown in FIGS. 12 and 13, the first joining layer 33 conductively bonds the second surface 321 of the second layer 32 and the first electrode 211 of the first semiconductor element 21. Thus, the first electrode 211 is electrically connected to the second layer 32. The dimension in the thickness direction z of the first joining layer 33 is smaller than the dimension t2 in the thickness direction z of the second layer 32. The composition of the first joining layer 33 includes aluminum (Al). Alternatively, the first joining layer 33 may consist of a metal layer containing aluminum in its composition and two silver layers provided on respective sides of the metal layer in the thickness direction z. The thickness of each of the two silver layers is smaller than that of the metal layer.

The first electrode 211 of the first semiconductor element 21 is conductively bonded to the second surface 321 of the second layer 32 by solid-phase diffusion via the first joining layer 33. Thus, as shown in FIG. 14, a first bonding layer 351 exists at the interface between the second surface 321 and the first joining layer 33. A second bonding layer 352 exists at the interface between the first joining layer 33 and the third electrode 221.

The first bonding layer 351 and the second bonding layer 352 are included in a solid-phase diffusion bonding layer 35. The solid-phase diffusion bonding layer 35 may be considered as a metallic bond region located at the interface between two mutually-contacting metal layers as a result of bonding these metal layers by solid-phase diffusion. Therefore, the solid-phase diffusion bonding layer 35 does not necessarily exist as a metallic bond layer with a definitely significant thickness. In an embodiment, the solid-phase diffusion bonding layer 35 may be observed as an area produced along the interface between the two metal layers, in which impurities or voids, diffused in during the solid-phase diffusion bonding process, remain.

As shown in FIGS. 12 and 13, the third joining layer 39 conductively bonds the first obverse surface 121 of the first conductive member 12 and the first surface 311 of the first layer 31. Thus, the first electrodes 211 of the first semiconductor elements 21 are electrically connected to the first conductive member 12 via the heat transfer layers 30. When the first surface 311 is conductively bonded to the first obverse surface 121 by solid-phase diffusion, the composition of the third joining layer 39 is the same as that of the first joining layer 33. Alternatively, the composition of the third joining layer 39 may be the same as that of the above-described conductive joining layer 29.

The first gate wiring layer 141 is supported on the substrate 11 as shown in FIGS. 2, 3, and 5. The first gate wiring layer 141 is located opposite to the second conductive member 13 with respect to the first conductive member 12 in the first direction X. The first gate wiring layer 141 extends along the second direction y. The composition of the first gate wiring layer 141 includes copper.

As shown in FIGS. 2 and 3, the first gate terminal 441 is located opposite to the first conductive member 12 with respect to the first gate wiring layer 141 in the first direction x. The first gate terminal 441 is electrically connected to the first gate wiring layer 141. The first gate terminal 441 is a metal lead made of a material containing copper or a copper alloy. As shown in FIGS. 1 and 5, a part of the first gate terminal 441 is covered with the sealing resin 60. The first gate terminal 441 is L-shaped as viewed in the second direction y. As shown in FIG. 5, the first gate terminal 441 includes a portion standing in the thickness direction z. This portion is exposed from the sealing resin 60. A gate voltage for driving the first semiconductor elements 21 is applied to the first gate terminal 441.

As shown in FIG. 3, the semiconductor module A10 further includes a plurality of first electrical connection members 51. As shown in FIG. 11, each of the first electrical connection members 51 is conductively bonded to the first gate electrode 213 of one of the first semiconductor elements 21 and the first gate wiring layer 141. Thus, the first gate electrodes 213 of the first semiconductor elements 21 are electrically connected to the first gate wiring layer 141. The first electrical connection members 51 are metal leads. The composition of the first electrical connection members 51 includes copper.

The second gate wiring layer 142 is supported on the substrate 11 as shown in FIGS. 2, 3, and 5. The second gate wiring layer 142 is located opposite to the first gate wiring layer 141 with respect to the first conductive member 12 and the second conductive member 13 in the first direction x. The second gate wiring layer 142 extends along the second direction y. The composition of the second gate wiring layer 142 includes copper.

As shown in FIGS. 2 and 3, the second gate terminal 442 is located opposite to the second conductive member 13 with respect to the second gate wiring layer 142 in the first direction x. The second gate terminal 442 is electrically connected to the second gate wiring layer 142. The second gate terminal 442 is a metal lead made of a material containing copper or a copper alloy. As shown in FIGS. 1 and 5, a part of the second gate terminal 442 is covered with the sealing resin 60. The second gate terminal 442 is L-shaped as viewed in the second direction y. As shown in FIG. 5, the second gate terminal 442 includes a portion standing in the thickness direction z. This portion is exposed from the sealing resin 60. A gate voltage for driving the second semiconductor elements 22 is applied to the second gate terminal 442.

As shown in FIG. 3, the semiconductor module A10 further includes a plurality of third electrical connection members 53. As shown in FIG. 9, each of the third electrical connection members 53 is conductively bonded to the second gate electrode 223 of one of the second semiconductor elements 22 and the second gate wiring layer 142. Thus, the second gate electrodes 223 of the second semiconductor elements 22 are electrically connected to the second gate wiring layer 142. The third electrical connection members 53 are wires. The composition of the third electrical connection members 53 includes gold (Au). Alternatively, the composition of the third electrical connection members 53 may include copper or aluminum.

As shown in FIG. 2, the semiconductor module A10 further includes two first wires 55. As shown in FIGS. 2 and 5, the two first wires 55 are individually bonded to the first gate terminal 441 and the second gate terminal 442 and to the first gate wiring layer 141 and the second gate wiring layer 142. Thus, the first gate terminal 441 is electrically connected to the first gate wiring layer 141, and the second gate terminal 442 is electrically connected to the second gate wiring layer 142. The composition of each of the two first wires 55 includes gold. Alternatively, the composition of the two first wires 55 may include copper or aluminum.

The first detection wiring layer 151 is supported on the substrate 11 as shown in FIGS. 2, 3, and 5. The first detection wiring layer 151 is located next to the first gate wiring layer 141 in the first direction x. The first detection wiring layer 151 extends along the second direction y. The composition of the first detection wiring layer 151 includes copper.

As shown in FIGS. 2 and 3, the first detection terminal 451 is located opposite to the first conductive member 12 with respect to the first detection wiring layer 151 in the first direction x. The first detection terminal 451 is located next to the first gate terminal 441 in the second direction y. The first detection terminal 451 is electrically connected to the first detection wiring layer 151. The first detection terminal 451 is a metal lead made of a material containing copper or a copper alloy. As shown in FIGS. 1 and 6, a part of the first detection terminal 451 is covered with the sealing resin 60. The first detection terminal 451 is L-shaped as viewed in the second direction y. As shown in FIG. 6, the first detection terminal 451 includes a portion standing in the thickness direction Z. This portion is exposed from the sealing resin 60. A voltage equal to the voltage applied to the first electrodes 211 of the first semiconductor elements 21 is applied to the first detection terminal 451.

As shown in FIG. 3, the semiconductor module A10 further includes a plurality of second electrical connection members 52. As shown in FIG. 11, each of the second electrical connection members 52 is conductively bonded to the third surface 312 of one of the heat transfer layers 30 and the first detection wiring layer 151. Thus, the first electrodes 211 of the first semiconductor elements 21 are electrically connected to the first detection wiring layer 151. The second electrical connection members 52 are wires. The composition of the second electrical connection members 52 includes gold. Alternatively, the composition of the second electrical connection members 52 may include copper or aluminum.

The second detection wiring layer 152 is supported on the substrate 11 as shown in FIGS. 2, 3, and 5. The second detection wiring layer 152 is located next to the second gate wiring layer 142 in the first direction x. The second detection wiring layer 152 extends along the second direction y. The composition of the second detection wiring layer 152 includes copper.

As shown in FIGS. 2 and 3, the second detection terminal 452 is located opposite to the second conductive member 13 with respect to the second detection wiring layer 152 in the first direction x. The second detection terminal 452 is located next to the second gate terminal 442 in the second direction y. The second detection terminal 452 is electrically connected to the second detection wiring layer 152. The second detection terminal 452 is a metal lead made of a material containing copper or a copper alloy. As shown in FIGS. 1 and 6, a part of the second detection terminal 452 is covered with the sealing resin 60. The second detection terminal 452 is L-shaped as viewed in the second direction y. As shown in FIG. 6, the second detection terminal 452 includes a portion standing in the thickness direction z. This portion is exposed from the sealing resin 60. A voltage equal to the voltage applied to the third electrodes 221 of the second semiconductor elements 22 is applied to the second detection terminal 452.

As shown in FIG. 3, the semiconductor module A10 further includes a plurality of fourth electrical connection members 54. As shown in FIG. 9, each of the fourth electrical connection members 54 is conductively bonded to the third electrode 221 of one of the second semiconductor elements 22 and the second detection wiring layer 152. Thus, the third electrodes 221 of the second semiconductor elements 22 are electrically connected to the second detection wiring layer 152. The fourth electrical connection members 54 are wires. The composition of the fourth electrical connection members 54 includes gold. Alternatively, the composition of the fourth electrical connection members 54 may include copper or aluminum.

As shown in FIG. 2, the semiconductor module A10 further includes two second wires 56. As shown in FIGS. 2 and 6, the two second wires 56 are individually bonded to the first detection terminal 451 and the second detection terminal 452 and to the first detection wiring layer 151 and the second detection wiring layer 152. Thus, the first detection terminal 451 is electrically connected to the first detection wiring layer 151, and the second detection terminal 452 is electrically connected to the second detection wiring layer 152. The composition of the two second wires 56 includes gold. Alternatively, the composition of the two second wires 56 may include copper or aluminum.

As shown in FIGS. 5 to 8, the third conductive member 16 is spaced apart from the substrate 11 toward the side that the first obverse surface 121 of the first conductive member 12 faces in the thickness direction z. The third conductive member 16 electrically connects the second electrodes 212 of the first semiconductor elements 21 and the third electrodes 221 of the second semiconductor elements 22. The composition of the third conductive member 16 includes copper. The third conductive member 16 has the shape of a flat plate.

As shown in FIGS. 2 and 5 to 8, the third conductive member 16 has a main portion 161, a plurality of first connecting portions 162, and a plurality of second connecting portions 163. The main portion 161 extends in the second direction y. As viewed in the thickness direction z, the main portion 161 overlaps with the first conductive member 12 and the second conductive member 13, and the region of the substrate 11 that is located between the first conductive member 12 and the second conductive member 13.

As shown in FIGS. 2 and 5, the first connecting portions 162 are connected to one side of the main portion 161 in the first direction x. The first connecting portions 162 extend in the first direction x and are arranged along the second direction y. As shown in FIG. 8, the first connecting portions 162 are conductively bonded to the second electrodes 212 of the first semiconductor elements 21 via the conductive joining layers 29, respectively. Thus, the second electrodes 212 of the first semiconductor elements 21 are electrically connected to the third conductive member 16.

As shown in FIGS. 2 and 5, the second connecting portions 163 are located opposite to the first connecting portions 162 with respect to the main portion 161 in the first direction X and connected to the main portion 161. The second connecting portions 163 extend in the first direction x and are arranged along the second direction y. As viewed in the thickness direction z, the shape and dimensions of each second connecting portion 163 are the same as the shape and dimensions of each first connecting portion 162. As shown in FIG. 7, the second connecting portions 163 are conductively bonded to the third electrodes 221 of the second semiconductor elements 22 via the conductive joining layers 29. Thus, the third electrodes 221 of the second semiconductor elements 22 are electrically connected to the third conductive member 16.

As shown in FIGS. 1 to 3, the first input terminal 41 is located on one side in the second direction y with respect to the substrate 11. As shown in FIG. 8, the first input terminal 41 is conductively bonded to the first conductive member 12. Thus, the first input terminal 41 is electrically connected to the first electrodes 211 of the first semiconductor elements 21 via the first conductive member 12 and the heat transfer layers 30. The first input terminal 41 is a metal plate made of a material containing copper or a copper alloy. A part of the first input terminal 41 is covered with the sealing resin 60. The first input terminal 41 has a first mounting hole 411 penetrating in the thickness direction z. The first mounting hole 411 is spaced apart from the sealing resin 60. The first input terminal 41 is an N terminal (negative electrode) to which a DC power supply voltage to be converted is applied.

As shown in FIGS. 1 to 3, the second input terminal 42 is located on the same side as the first input terminal 41 with respect to the substrate 11 in the second direction y. The second input terminal 42 is spaced apart from the first input terminal 41 in the first direction x. As shown in FIG. 7, the second input terminal 42 is conductively bonded to the second conductive member 13. Thus, the second input terminal 42 is electrically connected to the fourth electrodes 222 of the second semiconductor elements 22 via the second conductive member 13. The second input terminal 42 is a metal plate made of a material containing copper or a copper alloy. A part of the second input terminal 42 is covered with the sealing resin 60. The second input terminal 42 has a second mounting hole 421 penetrating in the thickness direction z. The second mounting hole 421 is spaced apart from the sealing resin 60. The second input terminal 42 is a P terminal (positive electrode) to which a DC power supply voltage to be converted is applied.

As shown in FIGS. 1 and 2, the output terminal 43 is located opposite to the first input terminal 41 and the second input terminal 42 with respect to the substrate 11 in the second direction y. As shown in FIG. 7, the output terminal 43 is spaced apart from the substrate 11 toward the side that the first obverse surface 121 of the first conductive member 12 faces in the thickness direction z. The output terminal 43 is conductively bonded to the main portion 161 of the third conductive member 16. Thus, the output terminal 43 is electrically connected to the second electrodes 212 of the first semiconductor elements 21 and the third electrodes 221 of the second semiconductor elements 22 via the third conductive member 16. The output terminal 43 is a metal plate made of a material containing copper or a copper alloy. A part of the output terminal 43 is covered with the sealing resin 60. The output terminal 43 has a third mounting hole 431 penetrating in the thickness direction z. The third mounting hole 431 is spaced apart from the sealing resin 60. The AC power converted by the first semiconductor elements 21 and the semiconductor elements 22 is outputted from the output terminal 43. As shown in FIGS. 1 and 5 to 8, the sealing resin 60 covers the first conductive member 12, the second conductive member 13, the first gate wiring layer 141, the second gate wiring layer 142, the first detection wiring layer 151, the second detection wiring layer 152, and the third conductive member 16. The sealing resin 60 also covers a part of each of the substrate 11, the first input terminal 41, the second input terminal 42, the output terminal 43, the first gate terminal 441, the second gate terminal 442, the first detection terminal 451 and the second detection terminal 452. The sealing resin 60 is electrically insulating. The sealing resin 60 is made of a material containing, for example, a black epoxy resin. A part of the sealing resin 60 is located between the substrate 11 and the main portion 161 of the third conductive member 16 in the thickness direction z.

As shown in FIGS. 1, 4, and 5 to 8, the sealing resin 60 has a top surface 61, a bottom surface 62, two first side surfaces 63, and two second side surfaces 64. The top surface 61 faces the same side as the first obverse surface 121 of the first conductive member 12 in the thickness direction z. The bottom surface 62 faces away from the top surface 61 in the thickness direction z. The heat dissipation layer 17 is exposed from the bottom surface 62.

As shown in FIGS. 1 and 4 to 6, the two first side surfaces 63 are spaced apart from each other in the first direction x and connected to the top surface 61 and the bottom surface 62. The first gate terminal 441 and the first detection terminal 451 are exposed from one of the two first side surfaces 63. The second gate terminal 442 and the second detection terminal 452 are exposed from the other one of the two first side surfaces 63.

As shown in FIGS. 1, 4, 7, and 8, the two second side surfaces 64 are spaced apart from each other in the second direction y and connected to the top surface 61 and the bottom surface 62. The first input terminal 41 and the second input terminal 42 are exposed from one of the two second side surfaces 64. The output terminal 43 is exposed from the other one of the two second side surfaces 64.

### Variation of the First Embodiment

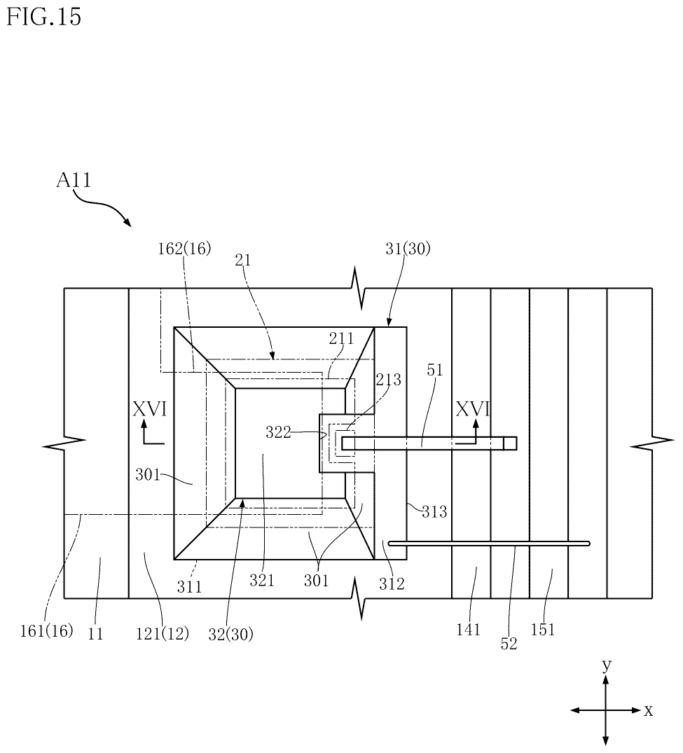

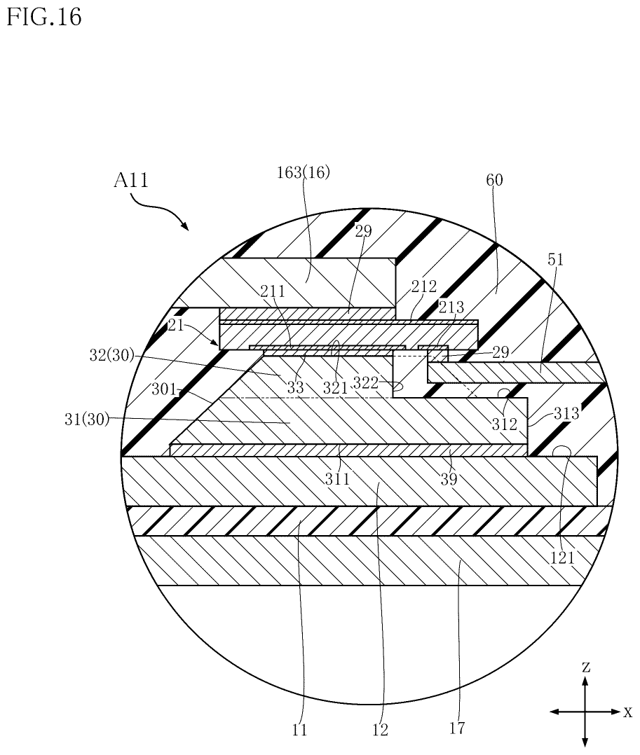

Next, a semiconductor module A11 as a variation of the semiconductor module A10 will be described based on FIGS. 15 and 16.

In the semiconductor module A11, each of the heat transfer layers 30 has a fifth surface 301 as shown in FIGS. 15 and 16. The fifth surface 301 is connected to the second surface 321 of the second layer 32. The fifth surface 301 is inclined with respect to the second surface 321 and overlaps with the first surface 311 of the first layer 31 as viewed in the thickness direction z. In the semiconductor module A11, the fifth surface 301 includes five regions. Three regions of the fifth surface 301 are connected to the second surface 321 and the first surface 311. The remaining two regions of the fifth surface 301 are connected to the second surface 321 and to the third surface 312 of the first layer 31. With such a configuration, a third surface 312 for conductively bonding one of the second electrical connection members 52 is provided in each heat transfer layer 30. The first layer 31 is not provided with the first recess 314.

Next, the effects of the semiconductor module A1 will be described.

The semiconductor module A10 includes the first semiconductor element 21 having the first electrode 211 and the first gate electrode 213 facing the first obverse surface 121 of the first conductive member 12, and the heat transfer layer 30 located between the first obverse surface 121 and the first semiconductor element 21. The heat transfer layer 30 is conductively bonded to the first obverse surface 121 and electrically connected to the first electrode 211. Such a configuration reduces the thermal resistance at the first obverse surface 121. The heat transfer layer 30 has the first surface 311 facing the first obverse surface 121 and the second surface 321 facing the first semiconductor element 21. As viewed in the thickness direction z, the second surface 321 is spaced apart from the first gate electrode 213. Such a configuration prevents the first gate electrode 213 and the first electrical connection member 51 shown in FIG. 12 from short-circuiting to the heat transfer layer 30.

As viewed in the thickness direction z, the second surface 321 is surrounded by the periphery of the first surface 311. When a hypothetical plane extending from the periphery of the second surface 321 toward the first surface 311 and forming an inclination angle of 45° with respect to the thickness direction z is defined in the heat transfer layer 30, the heat conducted to the heat transfer layer 30 diffuses uniformly in the area surrounded by the hypothetical plane. However, the present configuration allows the heat conducted through the second surface 321 into the heat transfer layer 30 to be easily diffused uniformly in the thickness direction z and the directions orthogonal to the thickness direction z. Thus, the heat conducted from the first electrode 211 of the first semiconductor element 21 to the heat transfer layer 30 is more quickly conducted to the first conductive member 12. Therefore, the semiconductor module A10 is capable of achieving improved heat dissipation of the semiconductor element (the first semiconductor element 21).

The heat transfer layer 30 includes the first layer having the first surface 311 and the second layer 32 having the second surface 321. The second layer 32 is located between the first layer 31 and the first electrode 211 of the first semiconductor element 21 and electrically connected to the first electrode 211. The first layer 31 has the third surface 312 facing away from the first surface 311 in the thickness direction z. As viewed in the thickness direction z, the first semiconductor element 21 is surrounded by the periphery of the third surface 312. Such a configuration makes longer the distance between the periphery of the second surface 321 and the periphery of the first surface 311 as viewed in the thickness direction z. Therefore, the heat conducted through the second surface 321 into the heat transfer layer 30 is easily diffused uniformly.

The dimension t1 in the thickness direction z of the first layer 31 is greater than the dimension t2 in the thickness direction z of the second layer 32. With such a configuration, heat diffuses in the directions orthogonal to the thickness direction z more easily in the first layer 31 than in the second layer 32. Therefore, the heat conducted through the second surface 321 into the heat transfer layer 30 is efficiently diffused in the heat transfer layer 30. To achieve efficient heat diffusion in the heat transfer layer 30 while suppressing the increase of the dimension in the thickness direction z of the semiconductor module A10, it is preferable that the dimension t1 is 3 to 30 times the dimension t2.

As viewed in the thickness direction z, the second layer 32 is surrounded by the periphery of the first semiconductor element 21. Also, as viewed in the thickness direction z, the area of the second surface 321 of the second layer 32 is smaller than that of the first electrode 211 of the first semiconductor element 21. Such a configuration makes further longer the distance between the periphery of the second surface 321 and the periphery of the first surface 311 as viewed in the thickness direction z. Therefore, the heat conducted through the second surface 321 into the heat transfer layer 30 is more efficiently diffused uniformly.

As viewed in the thickness direction z, the second layer 32 is spaced apart from the first gate electrode 213 of the first semiconductor element 21. Such a configuration provides a larger clearance between the heat transfer layer 30 and the first gate electrode 213 of the first semiconductor element 21. This is beneficial in preventing the first gate electrode 213 and the first electrical connection member 51 from short-circuiting to the heat transfer layer 30.

The first layer 31 is provided with the first recess 314 recessed from the third surface 312 and the fourth surface 313. As viewed in the thickness direction z, the first gate electrode 213 of the first semiconductor element 21 overlaps with the first recess 314. Such a configuration increases the clearance between the heat transfer layer 30 and the first gate electrode 213.

The heat transfer layer 30 further includes the first joining layer 33 conductively bonding the second surface 321 of the second layer 32 and the first electrode 211 of the first semiconductor element 21. The dimension in the thickness direction z of the first joining layer 33 is smaller than the dimension t2 in the thickness direction z of the second layer 32. Such a configuration allows the heat transfer layer 30 to be electrically connected to the first electrode 211 while reducing the thermal resistance at the interface between the heat transfer layer 30 and the first electrode 211.

Moreover, the solid-phase diffusion bonding layers 35 (the first bonding layer 351 and the second bonding layer 352 shown in FIG. 14) exist at the interface between the second surface 321 and the first joining layer 33 and the interface between the first joining layer 33 and the first electrode 211. Such a configuration further reduces the thermal resistance at the interface between the heat transfer layer 30 and the first electrode 211 as compared with the case where the first joining layer 33 is solder. In addition, the current flowing from the first electrode 211 to the heat transfer layer 30 can be increased.

The semiconductor module A10 further includes the third conductive member 16 located opposite to the first conductive member 12 and the second conductive member 13 with respect to the first semiconductor element 21 and the second semiconductor element 22 in the thickness direction z. The third conductive member 16 electrically connects the second electrode 212 of the first semiconductor element 21 and the third electrode 221 of the second semiconductor element 22. The polarity of the first electrode 211 of the first semiconductor element 21 and the polarity of the fourth electrode 222 of the second semiconductor element 22 differ from each other. As viewed in the thickness direction z, the third conductive member 16 overlaps with the region of the substrate 11 that is located between the first conductive member 12 and the second conductive member 13. Here, in the semiconductor module A10, a parasitic capacitance is formed by the third conductive member 16 and the heat dissipation layer 17 acting as electrode plates and the substrate 11 and the sealing resin 60 acting as dielectrics. Because the present configuration provides a longer distance between the third conductive member 16 and the heat dissipation layer 17 in the thickness direction z, the parasitic capacitance can be reduced. This suppresses the leakage current of the semiconductor module A10 caused by parasitic capacitance, thereby reducing the noise generated in semiconductor module A10.

The third conductive member 16 has the main portion 161 extending in the second direction y, the first connecting portions 162 located on one side of the main portion 161 in the first direction x, and the second connecting portions 163 located on the other side of the main portion 161 in the first direction x. As viewed in the thickness direction z, the shape and dimensions of each second connecting portion 163 are the same as the shape and dimensions of each first connecting portion 162. Such a configuration reduces the difference between the magnitude of the parasitic inductance from the second electrodes 212 of the first semiconductor elements 21 to the main portion 161 and the magnitude of the parasitic inductance from the third electrodes 221 of the second semiconductor elements 22 to the main portion 161. Therefore, the power loss from the second semiconductor elements 22 to the output terminal 43 and the power loss from the output terminal 43 to the first semiconductor elements 21 can be balanced.

The thickness of the substrate 11 is smaller than the thickness of each of the first conductive member 12 and the second conductive member 13. In other words, the thickness of each of the first conductive member 12 and the second conductive member 13 is greater than the thickness of the substrate 11. Such a configuration improves the efficiency of heat diffusion in the directions orthogonal to the thickness direction z in each of the first conductive member 12 and the second conductive member 13. Therefore, the heat dissipation of the semiconductor module A10 can be improved.

### Second Embodiment

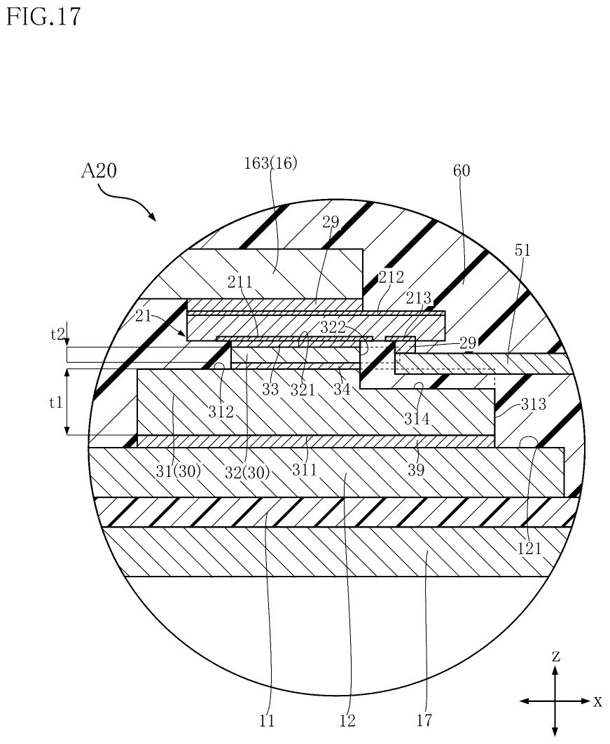

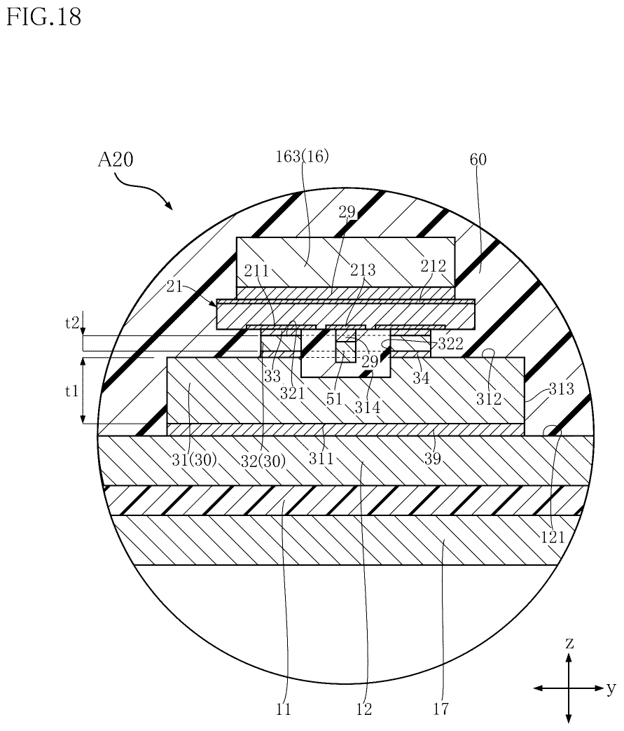

A semiconductor module A20 according to a second embodiment of the present disclosure will be described based on FIGS. 17 to 19. In these figures, the elements that are identical or similar to those of the semiconductor module A10 described above are denoted by the same reference signs, and the descriptions thereof are omitted. The sectional position of FIG. 17 is the same as that of FIG. 12, which shows the semiconductor module A10. The sectional position of FIG. 18 is the same as that of FIG. 13, which shows the semiconductor module A10.

The semiconductor module A20 differs from the semiconductor module A10 in configuration of the heat transfer layers 30.

As shown in FIGS. 17 and 18, each of the heat transfer layers 30 further includes a second joining layer 34. The second joining layer 34 conductively bonds the third surface 312 of the first layer 31 and the second layer 32. That is, in each of the heat transfer layers 30, the second layer 32 is configured separately from the first layer 31. The dimension in the thickness direction z of the second joining layer 34 is smaller than the dimension t2 in the thickness direction z of the second layer 32. The composition of the second joining layer 34 includes aluminum. Alternatively, the second joining layer 34 may consist of a metal layer containing aluminum in its composition and two silver layers provided on respective sides of the metal layer in the thickness direction z. The thickness of each of the two silver layers is smaller than that of the metal layer.

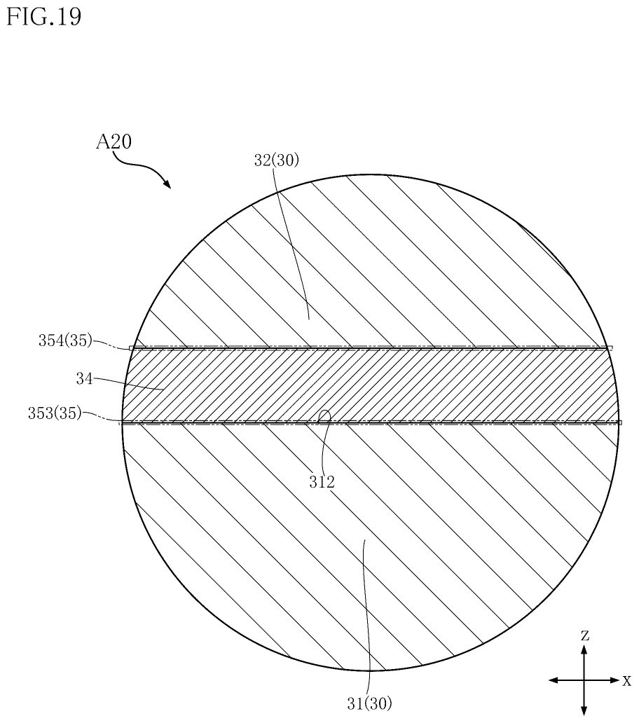

The second layer 32 is conductively bonded to the third surface 312 of the first layer 31 by solid-phase diffusion via the second joining layer 34. As a result, as shown in FIG. 19, a third bonding layer 353 exists at the interface between the third surface 312 of the first layer 31 and the second joining layer 34. A fourth bonding layer 354 exists at the interface between the second joining layer 34 and the second layer 32. The third bonding layer 353 and the fourth bonding layer 354 are included in the above-described solid-phase diffusion bonding layer 35.

In the semiconductor module A20, the thermal conductivity of the second layer 32 is higher than that of the first layer 31. When the composition of the first layer 31 includes copper, the composition of the second layer 32 includes silver, for example.

Next, the effects of the semiconductor module A20 will be described.

The semiconductor module A20 includes the first semiconductor element 21 having the first electrode 211 and the first gate electrode 213 facing the first obverse surface 121 of the first conductive member 12, and the heat transfer layer 30 located between the first obverse surface 121 and the first semiconductor element 21. The heat transfer layer 30 is conductively bonded to the first obverse surface 121 and electrically connected to the first electrode 211. The heat transfer layer 30 has the first surface 311 facing the first obverse surface 121 and the second surface 321 facing the first semiconductor element 21. As viewed in the thickness direction z, the second surface 321 is spaced apart from the first gate electrode 213. As viewed in the thickness direction z, the second surface 321 is surrounded by the periphery of the first surface 311. Thus, the semiconductor module A20 is also capable of achieving improved heat dissipation the of semiconductor element (the first semiconductor element 21). The semiconductor module A20 has a configuration similar to that of the semiconductor module A10, thereby achieving the same effects as the semiconductor module A10.

Each of the heat transfer layers 30 further includes the second joining layer 34. The second joining layer 34 conductively bonds the first layer 31 and the second layer 32. The dimension in the thickness direction z of the second joining layer 34 is smaller than the dimension t2 in the thickness direction z of the second layer 32. With such a configuration, when the first layer 31 and the second layer 32 are configured separately from each other, the thermal resistance at the interface between the first layer 31 and the second layer 32 is reduced while the function of the heat transfer layer 30 is ensured.

Moreover, the solid-phase diffusion bonding layers 35 (the third bonding layer 353 and the fourth bonding layer 354 shown in FIG. 19) exist at the interface between the first layer 31 and the second joining layer 34 and the interface between the second joining layer 34 and the second layer 32. Such a configuration further reduces the thermal resistance at the interface between the first layer 31 and the second layer 32 as compared with the case where the second joining layer 34 is solder. In addition, this configuration can increase the current flowing from the second layer 32 to the first layer 31 when the first layer 31 and the second layer 32 are configured separately from each other.

In the semiconductor module A20, because the first layer 31 and the second layer 32 are configured separately from each other, the thickness of the second layer 32 can be made smaller than that in the case of the semiconductor module A10. Also, the material of the second layer 32 can be different from that of the first layer 31. When the thickness of the second layer 32 is made small, the increase of the thermal resistance in the second layer 32 can be suppressed by making the thermal conductivity of the second layer 32 higher than that of the first layer 31.

### Third Embodiment

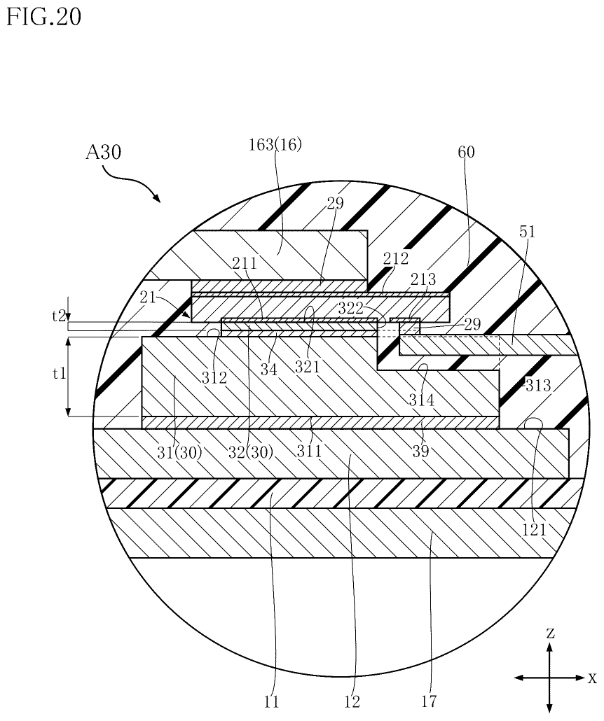

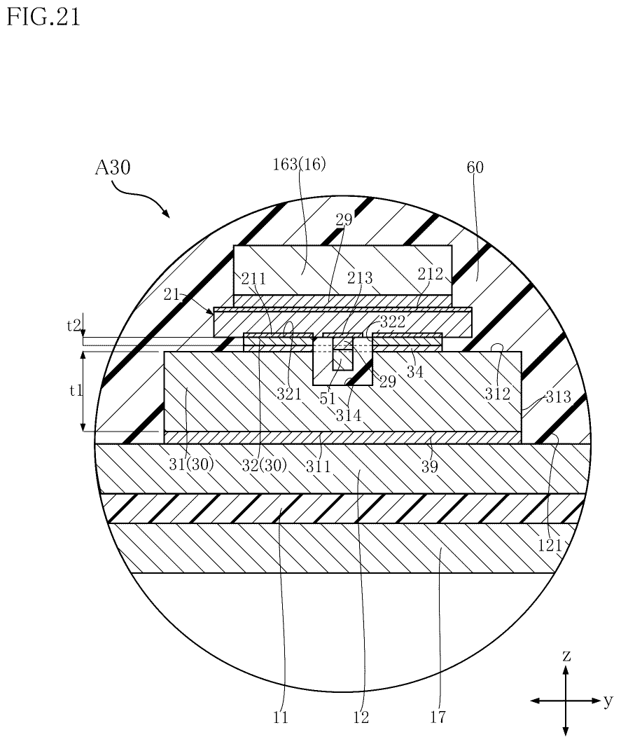

A semiconductor module A30 according to a third embodiment of the present disclosure will be described based on FIGS. 20 to 21. In these figures, the elements that are identical or similar to those of the semiconductor module A10 described above are denoted by the same reference signs, and the descriptions thereof are omitted. The sectional position of FIG. 20 is the same as that of FIG. 12, which shows the semiconductor module A10. The sectional position of FIG. 21 is the same as that of FIG. 13, which shows the semiconductor module A10.

The semiconductor module A30 differs from the semiconductor module A10 in configuration of the heat transfer layers 30.

As shown in FIGS. 20 and 21, each of the heat transfer layers 30 includes the second joining layer 34 similar to that of the semiconductor module A20, but does not include the first joining layer 33 similar to that of the semiconductor module A10 and the semiconductor module A20. Thus, the first electrodes 211 of the first semiconductor elements 21 are in contact with the second surfaces 321 of the second layers 32 of the heat transfer layers 30, respectively. In the semiconductor module A30, the second layers 32 of the heat transfer layers 30 are plating layers. The second layer 32 is formed integrally with the first electrode 211 by electrolytic plating during the manufacturing process of the first semiconductor elements 21.

As viewed in the thickness direction z, the area of the second surface 321 of the second layer 32 of each of the heat transfer layers 30 is equal to the area of the first electrode 211 of each of the first semiconductor elements 21. Therefore, the area of the second surface 321 of the second layer 32 in the semiconductor module A30 is greater than the area of the second surface 321 of the second layer 32 in the semiconductor module A10.

As with the semiconductor module A20, the second layer 32 is conductively bonded to the third surface 312 of the first layer 31 by solid-phase diffusion via the second joining layer 34. The thermal conductivity of the second layer 32 is higher than that of the first layer 31.

Next, the effects of the semiconductor module A30 will be described.

The semiconductor module A30 includes the first semiconductor element 21 having the first electrode 211 and the first gate electrode 213 facing the first obverse surface 121 of the first conductive member 12, and the heat transfer layer 30 located between the first obverse surface 121 and the first semiconductor element 21. The heat transfer layer 30 is conductively bonded to the first obverse surface 121 and electrically connected to the first electrode 211. The heat transfer layer 30 has the first surface 311 facing the first obverse surface 121 and the second surface 321 facing the first semiconductor element 21. As viewed in the thickness direction z, the second surface 321 is spaced apart from the first gate electrode 213. As viewed in the thickness direction z, the second surface 321 is surrounded by the periphery of the first surface 311. Thus, the semiconductor module A30 is also capable of achieving improved heat dissipation the of semiconductor element (the first semiconductor element 21). The semiconductor module A30 has a configuration similar to that of the semiconductor module A10, thereby achieving the same effects as the semiconductor module A10.

In the semiconductor module A30, the thickness of the second layer 32 can be made smaller than that in the case of the semiconductor module A20, because the first layer 31 and the second layer 32 are configured separately from each other and the second layer 32 is a plating layer integral with the first electrode 211 of the first semiconductor element 21. When the thickness of the second layer 32 is made small, the increase of the thermal resistance in the second layer 32 can be suppressed by making the thermal conductivity of the second layer 32 higher than that of the first layer 31.

### Fourth Embodiment

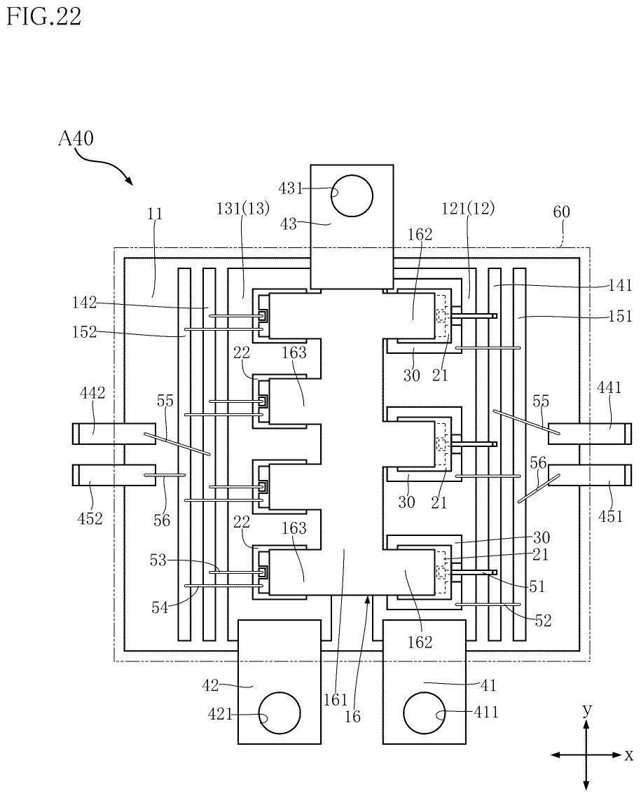

A semiconductor module A40 according to a fourth embodiment of the present disclosure will be described based on FIG. 22. In these figures, the elements that are identical or similar to those of the semiconductor module A10 described above are denoted by the same reference signs, and the descriptions thereof are omitted. For the convenience of understanding, the sealing resin 60 is transparent in FIG. 22. The outline of the sealing resin 60 is shown by imaginary lines in FIG. 22.

The semiconductor module A40 differs from the semiconductor module A10 in the number of heat transfer layers 30 and the number of first semiconductor elements 21.

As shown in FIG. 22, the first semiconductor element 21 includes at least one first semiconductor element 21. The second semiconductor element 22 includes at least one second semiconductor element 22. The number of the at least one first semiconductor element 21 and the number of the at least one second semiconductor element 22 differ from each other. In the semiconductor module A40, the number of the at least one first semiconductor element 21 is smaller than the number of the at least one second semiconductor element 22. Accordingly, the heat transfer layer 30 also includes at least one heat transfer layer 30, and the number of the at least one heat transfer layer 30 is smaller than the number of the at least one second semiconductor element 22 in the semiconductor module A40. Alternatively, the number of the at least one first semiconductor element 21 and the number of the at least one heat transfer layer 30 may be greater than the number of the at least one second semiconductor element 22.

Next, the effects of the semiconductor module A40 will be described.

The semiconductor module A40 includes the first semiconductor element 21 having the first electrode 211 and the first gate electrode 213 facing the first obverse surface 121 of the first conductive member 12, and the heat transfer layer 30 located between the first obverse surface 121 and the first semiconductor element 21. The heat transfer layer 30 is conductively bonded to the first obverse surface 121 and electrically connected to the first electrode 211. The heat transfer layer 30 has the first surface 311 facing the first obverse surface 121 and the second surface 321 facing the first semiconductor element 21. As viewed in the thickness direction z, the second surface 321 is spaced apart from the first gate electrode 213. As viewed in the thickness direction z, the second surface 321 is surrounded by the periphery of the first surface 311. Thus, the semiconductor module A40 is also capable of achieving improved heat dissipation of the semiconductor element (the first semiconductor element 21). The semiconductor module A40 has a configuration similar to that of the semiconductor module A10, thereby achieving the same effects as the semiconductor module A10.

The number of the at least one first semiconductor element 21 and the number of the at least one second semiconductor element 22 differ from each other. In the semiconductor module A40, the number of the at least one first semiconductor element 21 is smaller than the number of the at least one second semiconductor element 22. Such an arrangement further reduces the thermal resistance at the first obverse surface 121 of the first conductive member 12.

### Semiconductor Device B10

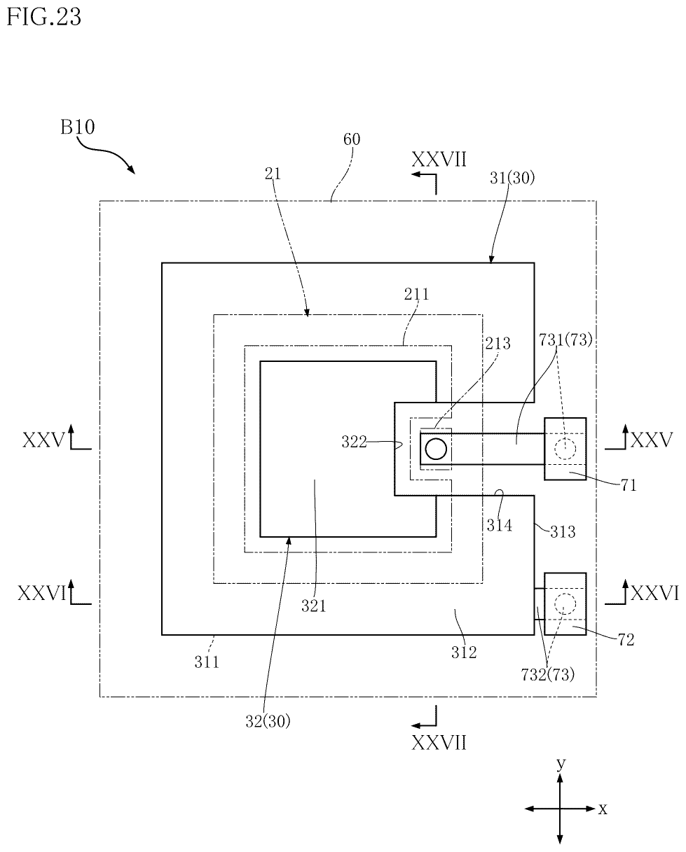

A semiconductor device B10 according to an embodiment of the present disclosure will be described based on FIGS. 23 to 28. In these figures, the elements that are identical or similar to those of the semiconductor module A10 described above are denoted by the same reference signs, and the descriptions thereof are omitted. For the convenience of understanding, the sealing 60 resin and the first semiconductor element 21 are transparent in FIG. 23. The outline of the sealing resin 60 and the first semiconductor element 21 are shown by imaginary lines in FIG. 23.

The semiconductor device B10 includes a first semiconductor element 21, a heat transfer layer 30, a sealing resin 60, a gate terminal 71, a detection terminal 72, a redistribution wiring 73, and a coating layer 74. Specifically, the semiconductor device B10 includes the first semiconductor element 21 corresponding to one of the first semiconductor elements 21 of the semiconductor module A10, and the heat transfer layer 30 to which the semiconductor element 21 is bonded. Therefore, in the semiconductor module A10, a plurality of semiconductor devices B10 can be mounted on the first conductive member 12, instead of the plurality of first semiconductor elements 21 and the plurality of heat transfer layers 30.

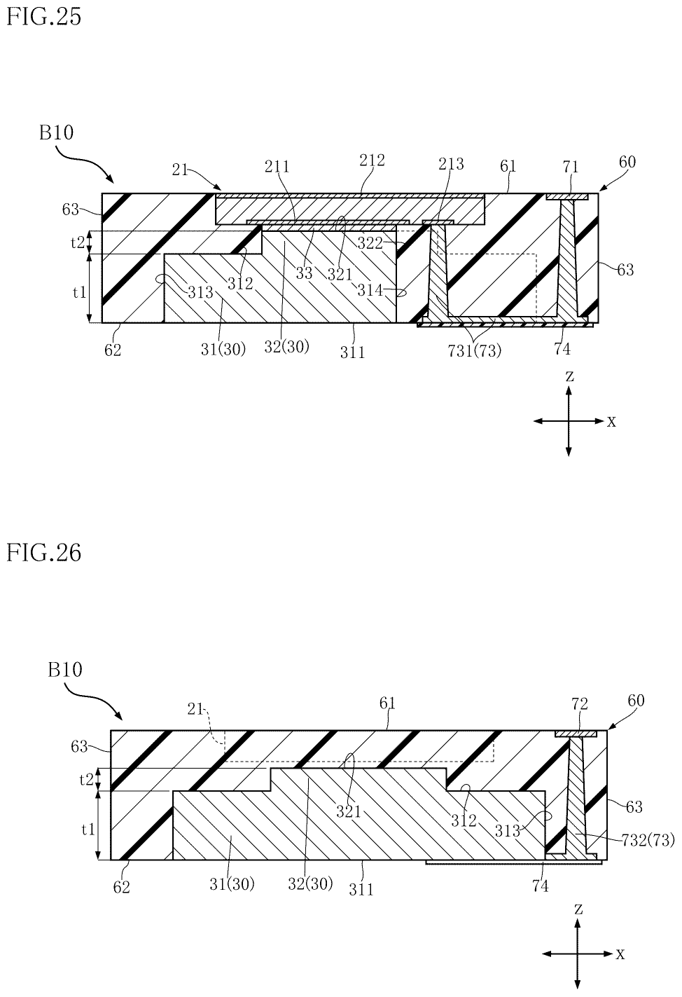

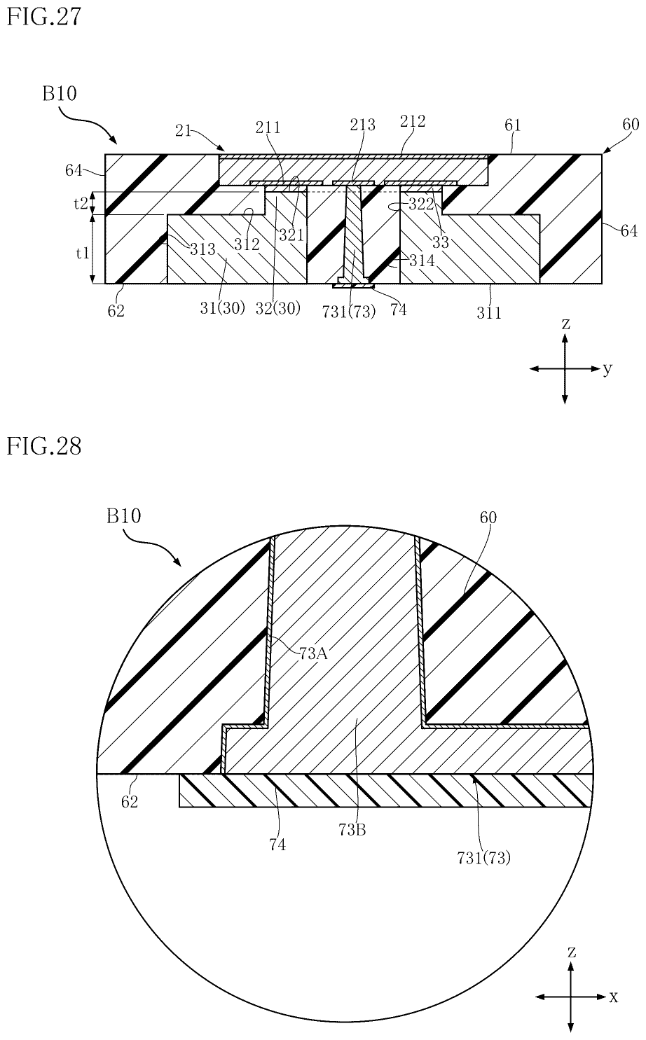

As shown in FIGS. 25 and 27, the heat transfer layer 30 includes the first layer 31, the second layer 32 and the first joining layer 33, as with the semiconductor module A10. The first electrode 211 of the first semiconductor element 21 is conductively bonded to the second surface 321 of the second layer 32 by solid-phase diffusion via the first joining layer 33.

The first recess 314 provided in the first layer 31 penetrates the first layer 31 in the thickness direction z, as with the second recess 322 provided in the second layer 32. As viewed in the thickness direction z, the first recess 314 overlaps with the entirety of the second recess 322.

The configuration of the heat transfer layer 30 in the semiconductor device B10 is the same as that in the semiconductor module A10. Alternatively, as the configuration of the heat transfer layer 30, the configuration of that in the semiconductor module A20 or the configuration of that in the semiconductor module A30 may be selected.

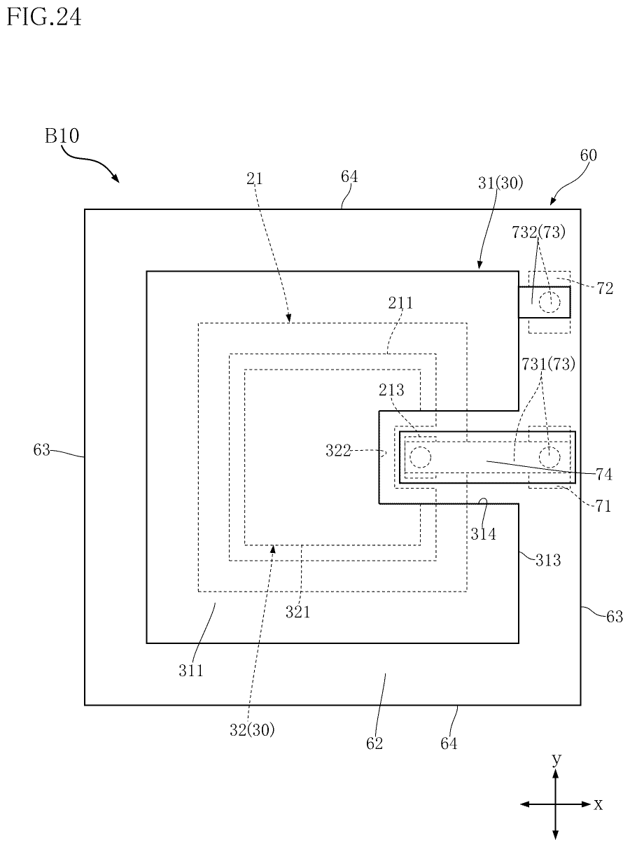

As shown in FIG. 24, the first surface 311 of the first layer 31 is exposed from the bottom surface 62 of the sealing resin 60. As shown in FIGS. 25 and 27, the second electrode 212 of the first semiconductor element 21 is exposed from the top surface 61 of the sealing resin 60.

As shown in FIGS. 25 and 26, the gate terminal 71 and the detection terminal 72 are located on the same side as the first semiconductor element 21 with respect to the heat transfer layer 30 in the thickness direction z. The detection terminal 72 is spaced apart from the gate terminal 71 in the first direction x. The gate terminal 71 and the detection terminal 72 are exposed from the top surface 61 of the sealing resin 60.

As shown in FIGS. 25 to 27, the redistribution wiring 73 is at least partially covered with the sealing resin 60. The redistribution wiring 73 includes a first redistribution wiring 731 and a second redistribution wiring 732. The first redistribution wiring 731 electrically connects the gate terminal 71 and the first gate electrode 213 of the first semiconductor element 21. Thus, the gate terminal 71 is electrically connected to the first gate electrode 213. The second redistribution wiring 732 electrically connects the detection terminal 72 and the first layer 31. Thus, the detection terminal 72 is electrically connected to the first electrode 211 of the first semiconductor element 21 via the heat transfer layer 30.

The redistribution wiring 73 includes sections extending in the first direction x and sections extending in the thickness direction z. In the first redistribution wiring 731, of the sections extending in the thickness direction z, the section connected to the first gate electrode 213 of the first semiconductor element 21 is housed in the first recess 314 of the first layer 31 and the second recess 322 of the second layer 32.

As shown in FIG. 28, the redistribution wiring 73 has a base layer 73A and a body layer 73B. Here, the sealing resin 60 contains an additive containing a metallic element. The base layer 73A is composed of the metallic element contained in the additive. The base layer 73A is in contact with the sealing resin 60. The body layer 73B covers the base layer 73A. The composition of the body layer 73B includes copper. The redistribution wiring 73 can be formed by the LDS (Laser Direct Structuring) technology, which is disclosed in U.S. Patent Application Publication No. 2010/0019370, for example.

The coating layer 74 covers a portion of the first redistribution wiring 731 of the redistribution wiring 73 that is exposed from the sealing resin 60. The coating layer 74 is electrically insulating. The coating layer 74 is in contact with the bottom surface 62 of the sealing resin 60 and the first redistribution wiring 731. The coating layer 74 is, for example, solder resist.

Next, the effects of the semiconductor device B10 will be described.

The semiconductor device B10 includes the first semiconductor element 21 having the first electrode 211 and the first gate electrode 213 located on one side in the thickness direction z, and the heat transfer layer 30 facing the first semiconductor element 21 and electrically connected to the first electrode 211. The heat transfer layer 30 has the first surface 311 facing opposite to the side facing the first semiconductor element 21 in the thickness direction z, and the second surface 321 facing the first semiconductor element 21. As viewed in the thickness direction z, the second surface 321 is spaced apart from the first gate electrode 213. As viewed in the thickness direction z, the second surface 321 is surrounded by the periphery of the first surface 311. Thus, the semiconductor device B10 is also capable of achieving improved heat dissipation of the semiconductor element (the first semiconductor element 21).

The semiconductor device B10 further includes the gate terminal 71 electrically connected to the first gate electrode 213 of the first semiconductor element 21. The gate terminal 71 is located on the same side as the first semiconductor element 21 with respect to the heat transfer layer 30 in the thickness direction z. With such a configuration, when the semiconductor device B10 is mounted on the semiconductor module A10, the gate terminal 71 is located on the same side as the second electrode 212 of the first semiconductor element 21 with respect to the heat transfer layer 30 in the thickness direction z. This allows the first electrical connection member 51, which electrically connects the first gate electrode 213 and the first gate wiring layer 141, to be easily conductively bonded to the gate terminal 71.

The present disclosure is not limited to the above-described embodiments. Various modifications in design may be made freely in the specific structure of the present disclosure.

The present disclosure includes the embodiments described in the following clauses.

Clause 1.

A semiconductor module comprising:
a first conductive member including a first obverse surface facing in a thickness direction;
at least one first semiconductor element including a first electrode and a first gate electrode that face the first obverse surface and a second electrode located on a side opposite to a side facing the first obverse surface in the thickness direction, the first electrode being electrically connected to the first conductive member; and
a heat transfer layer located between the first obverse surface and the first semiconductor element, conductively bonded to the first obverse surface, and electrically connected to the first electrode, wherein
the heat transfer layer includes a first surface facing the first obverse surface and a second surface facing the first semiconductor element,
the second surface is spaced apart from the first gate electrode as viewed in the thickness direction, and
the second surface is surrounded by a periphery of the first surface as viewed in the thickness direction.

Clause 2.

The semiconductor module according to clause 1, wherein the heat transfer layer includes a first layer including the first surface and conductively bonded to the first obverse surface and a second layer including the second surface and electrically connected to the first electrode,
the second layer is located between the first layer and the first electrode,
the first layer includes a third surface facing away from the first surface in the thickness direction, and
the first semiconductor element is surrounded by a periphery of the third surface as viewed in the thickness direction.

Clause 3.

The semiconductor module according to clause 2, wherein a dimension in the thickness direction of the first layer is greater than a dimension in the thickness direction of the second layer.

Clause 4.

The semiconductor module according to clause 3, wherein the dimension in the thickness direction of the first layer is 3 to 30 times the dimension in the thickness direction of the second layer.

Clause 5.

The semiconductor module according to clause 3 or 4, wherein the second layer is surrounded by a periphery of the first semiconductor element as viewed in the thickness direction.

Clause 6.

The semiconductor module according to clause 5, wherein an area of the second surface is smaller than an area of the first electrode.

Clause 7.

The semiconductor module according to any one of clauses 2 to 6, wherein the second layer is spaced apart from the first gate electrode as viewed in the thickness direction.

Clause 8.

The semiconductor module according to clause 7, wherein the first layer includes a fourth surface facing in a direction orthogonal to the thickness direction,
the first layer is provided with a first recess that is recessed from the third surface and the fourth surface, and
the first gate electrode overlaps with the first recess as viewed in the thickness direction.

Clause 9.

The semiconductor module according to any one of clauses 2 to 8, wherein the heat transfer layer includes a first joining layer conductively bonding the second surface and the first electrode, and
a dimension in the thickness direction of the first joining layer is smaller than the dimension in the thickness direction of the second layer.

Clause 10.

The semiconductor module according to clause 9, wherein a solid-phase diffusion bonding layer exists at an interface between the second surface and the first joining layer and an interface between the first joining layer and the first electrode.

Clause 11.

The semiconductor module according to clause 9 or 10, wherein the second layer is connected to the first layer at the third surface.

Clause 12.

The semiconductor module according to clause 9 or 10, wherein the heat transfer layer includes a second joining layer conductively bonding the first layer and the second layer, and
a dimension in the thickness direction of the second joining layer is smaller than the dimension in the thickness direction of the second layer.

Clause 13.

The semiconductor module according to clause 12, wherein thermal conductivity of the second layer is higher than thermal conductivity of the first layer.

Clause 14.

The semiconductor module according to any one of clauses 1 to 13, further comprising:
a second conductive member including a second obverse surface facing a same side as the first obverse surface in the thickness direction;
at least one second semiconductor element including a third electrode and a second gate electrode that are located on a side opposite to a side facing the second obverse surface in the thickness direction and a fourth electrode facing the second obverse surface, the fourth electrode being electrically connected to the second conductive member; and
a third conductive member electrically connecting the second electrode and the third electrode,
wherein a polarity of the first electrode and a polarity of the fourth electrode differ from each other.

Clause 15.

The semiconductor module according to clause 14, wherein the number of the at least one first semiconductor element and the number of the at least one second semiconductor element differ from each other.

Clause 16.

A semiconductor device comprising:
a semiconductor element including a first electrode and a first gate electrode that are located on one side in a thickness direction and a second electrode located on another side in the thickness direction; and
a heat transfer layer facing the semiconductor element and electrically connected to the first electrode, wherein
the heat transfer layer includes a first surface facing opposite to a side facing the semiconductor element in the thickness direction and a second surface facing the semiconductor element,
the second surface is spaced apart from the first gate electrode as viewed in the thickness direction, and
the second surface is surrounded by a periphery of the first surface as viewed in the thickness direction.

Clause 17.

The semiconductor device according to clause 16, further comprising a sealing resin,
wherein the first surface and the second electrode are exposed from the sealing resin.

Clause 18.

The semiconductor device according to clause 17, further comprising:
a gate terminal exposed from the sealing resin; and
a first redistribution wiring electrically connecting the gate terminal and the first gate electrode, wherein
the gate terminal is located on the same side as the semiconductor element with respect to the heat transfer layer in the thickness direction, and
the first redistribution wiring is at least partially covered with the sealing resin.

### REFERENCE NUMERALS

A10, A20, A30, A40: Semiconductor module
B10: Semiconductor device
11: Substrate
12: First conductive member
121: First obverse surface
13: Second conductive member
131: Second obverse surface
141: First gate wiring layer
142: Second gate wiring layer
151: First detection wiring layer
152: Second detection wiring layer
16: Third conductive member
161: Main portion
162: First connecting portion
163: Second connecting portion
17: Heat dissipation layer
21: First semiconductor element
211: First electrode
212: Second electrode
213: First gate electrode
22: Second semiconductor element
221: Third electrode
222: Fourth electrode
223: Second gate electrode
29: Conductive joining layer
30: Heat transfer layer
301: Fifth surface
31: First layer
311: First surface
312: Third surface
313: Fourth surface
314: First recess
32: Second layer
321: Second surface
322: Second recess
33: First joining layer
34: Second joining layer
35: Solid-phase diffusion bonding layer
351: First bonding layer
352: Second bonding layer
353: Third bonding layer
354: Fourth bonding layer
39: Third joining layer
41: First input terminal
411: First mounting hole
42: Second input terminal
421: Second mounting hole
43: Output terminal
431: Third mounting hole
441: First gate terminal
442: Second gate terminal
451: First detection terminal
452: Second detection terminal
51: First electrical connection member
52: Second electrical connection member
53: Third electrical connection member
54: Fourth electrical connection member
55: First wire
56: Second wire
60: Sealing resin
61: Top surface
62: Bottom surface
63: First side surface
64: Second side surface
71: Gate terminal
72: Detection terminal
73: Redistribution wiring
73A: Base layer
73B: Body layer
731: First redistribution wiring
732: Second redistribution wiring
74: Coating layer
z: Thickness direction
x: First direction
y: Second direction

1. A semiconductor module comprising:
a first conductive member including a first obverse surface facing in a thickness direction;
at least one first semiconductor element including a first electrode and a first gate electrode that face the first obverse surface and a second electrode located on a side opposite to a side facing the first obverse surface in the thickness direction, the first electrode being electrically connected to the first conductive member; and
a heat transfer layer located between the first obverse surface and the first semiconductor element, conductively bonded to the first obverse surface, and electrically connected to the first electrode, wherein
the heat transfer layer includes a first surface facing the first obverse surface and a second surface facing the first semiconductor element,
the second surface is spaced apart from the first gate electrode as viewed in the thickness direction, and
the second surface is surrounded by a periphery of the first surface as viewed in the thickness direction.

2. The semiconductor module according to claim 1, wherein the heat transfer layer includes a first layer including the first surface and conductively bonded to the first obverse surface and a second layer including the second surface and electrically connected to the first electrode,
the second layer is located between the first layer and the first electrode,
the first layer includes a third surface facing away from the first surface in the thickness direction, and the first semiconductor element is surrounded by a periphery of the third surface as viewed in the thickness direction.

3. The semiconductor module according to claim 2, wherein a dimension in the thickness direction of the first layer is greater than a dimension in the thickness direction of the second layer.

4. The semiconductor module according to claim 3, wherein the dimension in the thickness direction of the first layer is 3 to 30 times the dimension in the thickness direction of the second layer.

5. The semiconductor module according to claim 3, wherein the second layer is surrounded by a periphery of the first semiconductor element as viewed in the thickness direction.

6. The semiconductor module according to claim 5, wherein an area of the second surface is smaller than an area of the first electrode.

7. The semiconductor module according to claim 2, wherein the second layer is spaced apart from the first gate electrode as viewed in the thickness direction.

8. The semiconductor module according to claim 7, wherein the first layer includes a fourth surface facing in a direction orthogonal to the thickness direction,
the first layer is provided with a first recess that is recessed from the third surface and the fourth surface, and
the first gate electrode overlaps with the first recess as viewed in the thickness direction.

9. The semiconductor module according to claim 2, wherein the heat transfer layer includes a first joining layer conductively bonding the second surface and the first electrode, and
a dimension in the thickness direction of the first joining layer is smaller than the dimension in the thickness direction of the second layer.

10. The semiconductor module according to claim 9, wherein a solid-phase diffusion bonding layer exists at an interface between the second surface and the first joining layer and an interface between the first joining layer and the first electrode.

11. The semiconductor module according to claim 9, wherein the second layer is connected to the first layer at the third surface.

12. The semiconductor module according to claim 9, wherein the heat transfer layer includes a second joining layer conductively bonding the first layer and the second layer, and
a dimension in the thickness direction of the second joining layer is smaller than the dimension in the thickness direction of the second layer.

13. The semiconductor module according to claim 12, wherein thermal conductivity of the second layer is higher than thermal conductivity of the first layer.

14. The semiconductor module according to claim 1, further comprising:
a second conductive member including a second obverse surface facing a same side as the first obverse surface in the thickness direction;
at least one second semiconductor element including a third electrode and a second gate electrode that are located on a side opposite to a side facing the second obverse surface in the thickness direction and a fourth electrode facing the second obverse surface, the fourth electrode being electrically connected to the second conductive member; and
a third conductive member electrically connecting the second electrode and the third electrode,
wherein a polarity of the first electrode and a polarity of the fourth electrode differ from each other.

15. The semiconductor module according to claim 14, wherein the number of the at least one first semiconductor element and the number of the at least one second semiconductor element differ from each other.

16. A semiconductor device comprising:
a semiconductor element including a first electrode and a first gate electrode that are located on one side in a thickness direction and a second electrode located on another side in the thickness direction; and
a heat transfer layer facing the semiconductor element and electrically connected to the first electrode, wherein
the heat transfer layer includes a first surface facing opposite to a side facing the semiconductor element in the thickness direction and a second surface facing the semiconductor element,
the second surface is spaced apart from the first gate electrode as viewed in the thickness direction, and
the second surface is surrounded by a periphery of the first surface as viewed in the thickness direction.

17. The semiconductor device according to claim 16, further comprising a sealing resin,
wherein the first surface and the second electrode are exposed from the sealing resin.

18. The semiconductor device according to claim 17, further comprising:
a gate terminal exposed from the sealing resin; and
a first redistribution wiring electrically connecting the gate terminal and the first gate electrode, wherein
the gate terminal is located on the same side as the semiconductor element with respect to the heat transfer layer in the thickness direction, and
the first redistribution wiring is at least partially covered with the sealing resin.
